(19) United States
(12) Patent Application Publication
(10) Pub. No.: US 2026/0068353 A1
(43) Pub. Date: Mar. 5, 2026

(54) INTERBAND PHOTODETECTOR

(71) Applicant: HAMAMATSU PHOTONICS K.K., Hamamatsu-shi (JP)

(72) Inventors: Masahiro HITAKA, Shizuoka (JP); Kazuue FUJITA, Shizuoka (JP)

(21) Appl. No.: 19/284,674

(22) Filed: Jul. 30, 2025

(30) Foreign Application Priority Data
Aug. 29, 2024 (JP) 2024-147380

(51) Int. Cl. H10F 77/14; H10F 30/223

(52) U.S. Cl. CPC H10F 77/146; H10F 30/223

(57) ABSTRACT

An interband photodetector includes a semiconductor substrate, and a superlattice layer provided on the semiconductor substrate, and including a unit layered structure having a type-I quantum well structure. The unit layered structure includes an absorption region including at least one quantum well layer, and a relaxation region including m quantum well layers. The absorption region has a detection lower level arising from a level in a valence band in the quantum well layer, and a detection upper level arising from a level in a conduction band, and the relaxation region has m relaxation levels each arising from a level in the conduction band in each of the m quantum well layers. The photodetector detects light by interband absorption from the detection lower level to the detection upper level, and electrons excited by light absorption are extracted via the m relaxation levels.

### CROSS-REFERENCE TO RELATED APPLICATION

This application is based upon and claims the benefit of priority from Japanese Patent Application No. 2024-147380, filed on Aug. 29, 2024, the entire contents of which are incorporated herein by reference.

### TECHNICAL FIELD

The present disclosure relates to an interband photodetector using interband light absorption in a quantum well structure.

### BACKGROUND

In recent years, as a photodetector in a mid-infrared wavelength region and the like, a quantum cascade detector (QCD), which uses a cascade structure in which unit layered structures each having a quantum well structure are stacked, has been reported. The quantum cascade detector is a photodetector for detecting incident light by absorbing the light in the cascade structure and measuring a current amount flowing due to carriers generated by the light absorption, and is characterized by the capability of high-speed operation without applying bias. Further, in the quantum cascade detector, it is possible to absorb and detect the light more efficiently by cascade-coupling, in multiple stages, semiconductor layered structures each including an absorption well layer for absorbing the light (see, for example, Patent Document 1).
Patent Document 1: Japanese Patent Application Laid-Open Publication No. 2015-88688
Patent Document 2: US Patent Application Publication No. 2007/0224721
Non Patent Document 1: L. M. Kruger et al., “High-speed interband cascade infrared photodetectors: photo-response saturation by a femtosecond oscillator”, Optics Express Vol. 29, No. 9 (2021) pp. 14087-14100

### SUMMARY

In the quantum cascade detector described above, the light is detected by using an intersubband electron transition in a subband level structure formed in the quantum well structure. Therefore, even when the degree of freedom in designing the quantum well structure is considered, the quantum cascade detector can detect only the light having a wavelength corresponding to an energy difference between subbands (for example, mid-infrared light), and it is difficult to apply the detector to detection of the light over a wide wavelength range.

On the other hand, separately from the quantum cascade detector, an interband cascade detector (ICD) using an interband electron transition in the quantum well structure has been proposed (see, for example, Patent Document 2 and Non Patent Document 1). Further, in the conventional interband cascade detector, a type-II quantum well structure is mainly used.

However, semiconductor materials which can be used for the type-II quantum well structure are limited, and it may not be possible to sufficiently obtain the degree of freedom in designing the quantum well structure corresponding to a desired detection wavelength of the light. For example, in the case of Sb-based semiconductor materials used in the conventional interband cascade detector, there is a limitation in shortening the detection wavelength, and, similarly to the quantum cascade detector, it is difficult to apply the detector to detection of the light over a wide wavelength range.

An object of the present invention is to provide a semiconductor photodetector capable of being suitably applied to detection of light at a desired detection wavelength in a wide wavelength range.

An embodiment of the present invention is an interband photodetector. The interband photodetector includes (1) a semiconductor substrate; and (2) a superlattice layer provided on the semiconductor substrate, and including a unit layered structure having a type-I quantum well structure including n quantum barrier layers and n quantum well layers, where n is an integer of 3 or more, and (3) the unit layered structure includes an absorption region including at least one quantum well layer, and a relaxation region including m quantum well layers, where m is an integer from 2 to n−1, the absorption region has, in its level structure, a detection lower level arising from a level in a valence band in the quantum well layer included in the absorption region and functioning as an absorption well layer, and a detection upper level arising from a level in a conduction band, the relaxation region has, in its level structure, m relaxation levels each arising from a level in the conduction band in each of the m quantum well layers included in the relaxation region, and (4) detection target light is detected by interband absorption from the detection lower level to the detection upper level in the absorption region, and electrons excited by the interband absorption are extracted via a relaxation level structure formed by the m relaxation levels in the relaxation region.

In the interband photodetector described above, as the active layer for detecting the detection target light, the superlattice layer including the unit layered structure of the type-I quantum well structure is used, in which the first barrier layer to the n-th barrier layer and the first well layer to the n-th well layer are alternately stacked, and which includes the absorption region used for absorption and detection of the light and the relaxation region used for relaxation and extraction of the electrons. In addition, the detection target light is detected by the interband absorption between the detection lower level of the valence band and the detection upper level of the conduction band in the absorption region, and the electrons are extracted by the relaxation via the m relaxation levels in the relaxation region.

According to the above configuration, by using the interband electron transition instead of the intersubband electron transition for the detection of the detection target light, a detection wavelength of the light can be suitably set by designing a band gap in the quantum well structure and the like. Further, by using the type-I quantum well structure as the quantum well structure in the unit layered structure of the superlattice layer, compared with the case of using the type-II quantum well structure, the degree of freedom in selecting the semiconductor materials and designing the quantum well structure can be increased, and the photodetector can be suitably applied to the detection of the light at a desired detection wavelength over a wide wavelength range.

According to the interband photodetector of the present invention, a semiconductor photodetector capable of being suitably applied to detection of light at a desired detection wavelength in a wide wavelength range can be realized.

The present invention will be more fully understood from the detailed description given hereinbelow and the accompanying drawings, which are given by way of illustration only and are not to be considered as limiting the present invention.

Further scope of applicability of the present invention will become apparent from the detailed description given hereinafter.

However, it should be understood that the detailed description and specific examples, while indicating preferred embodiments of the invention, are given by way of illustration only, since various changes and modifications within the spirit and scope of the invention will be apparent to those skilled in the art from this detailed description.

### BRIEF DESCRIPTION OF THE DRAWINGS

FIG. 1 is a diagram illustrating a basic configuration of a first embodiment of an interband photodetector.

FIG. 2 is a diagram illustrating a type-I quantum well structure and a level structure in a superlattice layer included in the interband photodetector.

FIG. 3 is a diagram illustrating a type-II quantum well structure in a conventional interband cascade detector.

FIG. 4 is a graph illustrating a specific example of a configuration of a unit layered structure constituting the superlattice layer.

FIG. 5 is a table showing an example of a semiconductor layered structure in the interband photodetector illustrated in FIG. 1.

FIG. 6 is a table showing an example of a layered structure in the superlattice layer of the interband photodetector illustrated in FIG. 1.

FIG. 7 is a perspective view schematically illustrating an example of a configuration of a photodetection element using the interband photodetector.

FIG. 8A and FIG. 8B are side views each schematically illustrating an example of the configuration of the photodetection element using the interband photodetector.

FIG. 9 is a graph showing a photodetection spectrum acquired by the photodetection element using the interband photodetector.

FIG. 10 is a diagram illustrating a first modification of the quantum well structure and the level structure in the superlattice layer included in the interband photodetector.

FIG. 11 is a diagram illustrating a second modification of the quantum well structure and the level structure in the superlattice layer included in the interband photodetector.

FIG. 12 is a diagram illustrating a basic configuration of a second embodiment of the interband photodetector.

FIG. 13 is a table showing an example of the semiconductor layered structure in the interband photodetector illustrated in FIG. 12.

FIG. 14 is a diagram illustrating a basic configuration of a third embodiment of the interband photodetector.

FIG. 15 is a table showing an example of the semiconductor layered structure in the interband photodetector illustrated in FIG. 14.

FIG. 16 is a diagram illustrating a basic configuration of a fourth embodiment of the interband photodetector.

FIG. 17 is a table showing an example of the semiconductor layered structure in the interband photodetector illustrated in FIG. 16.

FIG. 18 is a diagram illustrating a basic configuration of a fifth embodiment of the interband photodetector.

FIG. 19 is a table showing an example of the semiconductor layered structure in the interband photodetector illustrated in FIG. 18.

FIG. 20 is a diagram illustrating a basic configuration of a sixth embodiment of the interband photodetector.

FIG. 21 is a table showing an example of the semiconductor layered structure in the interband photodetector illustrated in FIG. 20.

FIG. 22 is a diagram illustrating a basic configuration of a seventh embodiment of the interband photodetector.

FIG. 23 is a table showing an example of the semiconductor layered structure in the interband photodetector illustrated in FIG. 22.

FIG. 24 is a diagram illustrating a basic configuration of an eighth embodiment of the interband photodetector.

FIG. 25 is a table showing an example of the semiconductor layered structure in the interband photodetector illustrated in FIG. 24.

FIG. 26 is a diagram illustrating a basic configuration of a ninth embodiment of the interband photodetector.

FIG. 27 is a table showing an example of the semiconductor layered structure in the interband photodetector illustrated in FIG. 26.

FIG. 28 is a diagram illustrating a basic configuration of a tenth embodiment of the interband photodetector.

FIG. 29 is a table showing an example of the semiconductor layered structure in the interband photodetector illustrated in FIG. 28.

FIG. 30 is a diagram illustrating a basic configuration of an eleventh embodiment of the interband photodetector.

FIG. 31 is a table showing an example of the semiconductor layered structure in the interband photodetector illustrated in FIG. 30.

FIG. 32 is a diagram illustrating a basic configuration of a twelfth embodiment of the interband photodetector.

FIG. 33 is a table showing an example of the semiconductor layered structure in the interband photodetector illustrated in FIG. 32.

### DETAILED DESCRIPTION

Hereinafter, embodiments of an interband photodetector will be described in detail with reference to the accompanying drawings. In the description of the drawings, the same elements will be denoted by the same reference signs, and redundant description will be omitted. Further, the dimensional ratios in the drawings are not always coincident with those in the description.

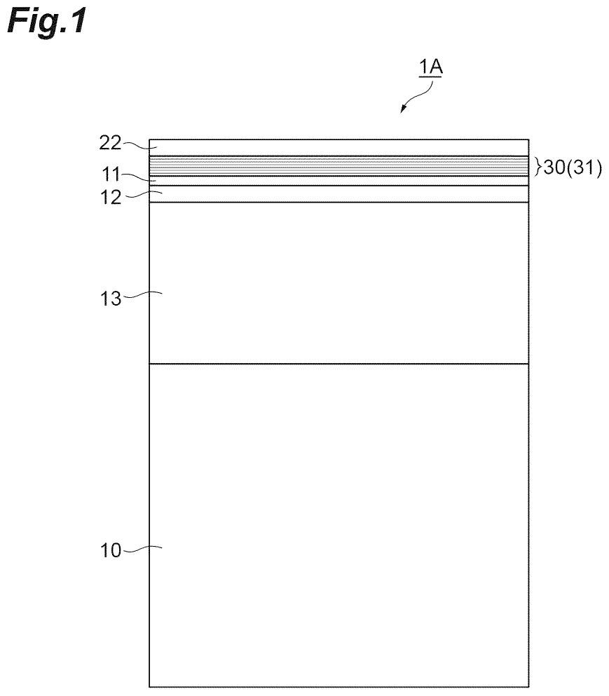

FIG. 1 is a diagram schematically illustrating a basic configuration of a first embodiment of a interband photodetector by a semiconductor layered structure. The interband photodetector 1A according to the present embodiment is a photodetector for detecting light by using light absorption due to an interband electron excitation in a semiconductor quantum well structure. The interband photodetector 1A is configured to include a semiconductor substrate 10, and a superlattice layer 30 formed on the semiconductor substrate 10.

The superlattice layer 30 includes a single or a plurality of unit layered structures 31, each including an absorption region (a light absorption layer) used for absorption and detection of the light, and a relaxation region (an electron relaxation layer) used for relaxation and extraction of electrons as carriers. The number of units of the unit layered structure 31 in the superlattice layer 30 is appropriately set according to the photodetection characteristics and the like required for the photodetector 1A. In the present embodiment, the number of units of the unit layered structure 31 constituting the superlattice layer 30 is set to one. Further, in general, the superlattice layer 30 is formed directly on the semiconductor substrate 10, or formed via another semiconductor layer.

In the configuration illustrated in FIG. 1, in a region between the semiconductor substrate 10 and the superlattice layer 30 on the side of the semiconductor substrate 10 with respect to the superlattice layer 30, an n-type low refractive index layer 13, an n-type contact layer 12, and a carrier block layer 11 are provided in this order from the side of the semiconductor substrate 10, and the carrier block layer 11 is in contact with a lower surface of the superlattice layer 30. Further, in a region on the side opposite to the semiconductor substrate 10 with respect to the superlattice layer 30, an n-type contact layer 22 is provided, and the n-type contact layer 22 is in contact with an upper surface of the superlattice layer 30.

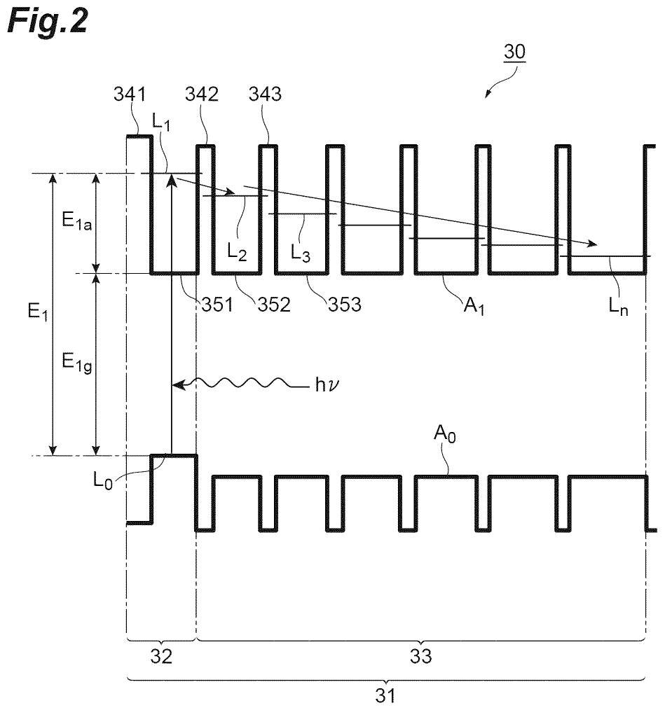

FIG. 2 is a diagram illustrating a quantum well structure and a level structure in the superlattice layer 30 included in the interband photodetector 1A illustrated in FIG. 1. As illustrated in FIG. 2, the unit layered structure 31 included in the superlattice layer 30 is constituted by using, with n being set to an integer of 3 or more, n quantum barrier layers and n quantum well layers.

The n barrier layers and the n well layers described above are formed in the order, from the left side in the diagram, of a first barrier layer 341, a first well layer 351, a second barrier layer 342, a second well layer 352, a third barrier layer 343, a third well layer 353, . . . , an n-th barrier layer, and an n-th well layer. Further, in the unit layered structure 31, each of the n quantum barrier layers and the n quantum well layers described above is preferably formed of an i-type semiconductor layer.

The unit layered structure 31 constituting the superlattice layer 30 is, in general, configured to include, with m being set to an integer of 2 or more and n−1 or less, an absorption region 32 including at least one quantum well layer, and a relaxation region 33 including m quantum well layers.

In the configuration illustrated in FIG. 2, out of the respective semiconductor layers constituting the unit layered structure 31, the absorption region 32 is formed by the first barrier layer 341 and the first well layer 351, and further, the relaxation region 33 is formed by the second barrier layer 342 to the n-th well layer. Further, in FIG. 2, for each of the semiconductor layers in the unit layered structure 31, a valence band upper edge A₀ and a conduction band lower edge A₁ are illustrated. An energy difference between the valence band upper edge A₀ and the conduction band lower edge A₁ is a band gap energy E_{g}.

In the present embodiment, the unit layered structure 31 of the superlattice layer 30 is configured to have a type-I quantum well structure over the entire structure including the absorption region 32 and the relaxation region 33. In the configuration illustrated in FIG. 2, as to the conduction band lower edge A₁, the conduction band lower edge in the quantum well layer is lower than the conduction band lower edge in the adjacent quantum barrier layer, and thus, the quantum well structure is formed. On the other hand, as to the valence band upper edge A₀, in the type-I quantum well structure described above, the valence band upper edge in the quantum well layer is set higher than the valence band upper edge in the adjacent quantum barrier layer.

In addition, in a type-II quantum well structure, on the contrary to the type-I quantum well structure, the valence band upper edge in the quantum well layer is set lower than the valence band upper edge in the adjacent quantum barrier layer. The above types of the quantum well structure, and the characteristics of the interband photodetector in the case of using each of the types and the like will be described later.

In the configuration illustrated in FIG. 2, as described above, the absorption region 32 is configured to include the first well layer 351 as a single quantum well layer. Further, the relaxation region 33 is configured to include the second well layer 352 to the n-th well layer as the m=n−1 quantum well layers.

The absorption region 32 has, in its level structure, a detection lower level L₀ arising from a level in the valence band in the first well layer 351 included in the absorption region 32 and functioning as an absorption well layer, and a detection upper level L₁ arising from a level in the conduction band. Further, the relaxation region 33 has, in its level structure, n−1 relaxation levels L₂ to Lₙ, each arising from a level in the conduction band in each of the second well layer 352 to the n-th well layer included in the relaxation region 33.

In the first well layer 351 included in the absorption region 32, the detection upper level L₁ is preferably a level arising from a ground level in a subband level structure in the conduction band. In a similar way, in the k-th well layer which is each of the second well layer 352 to the n-th well layer included in the relaxation region 33, the relaxation level Lₖ is preferably a level arising from a ground level in a subband level structure in the conduction band.

In the above configuration, the superlattice layer 30 in the photodetector 1A detects light hv, which is incident on the photodetector 1A as detection target light, by interband absorption from the detection lower level L₀ to the detection upper level L₁ in the absorption region 32. In addition, electrons excited by the interband absorption are extracted via a relaxation level structure formed by the n−1 relaxation levels L₂ to Lₙ in the relaxation region 33, and thus, the detection target light is detected by measuring the resulting current amount.

Further, in the absorption region 32, an energy difference E₁ between the detection lower level L₀ and the detection upper level L₁, which corresponds to a detection energy of the detection target light hv, as illustrated in FIG. 2, is obtained as E₁=E_{1g}+E₁ₐ, which is a sum of a band gap energy E_{1g} in the first well layer 351 and an energy difference E₁ₐ between the conduction band lower edge A₁ and the detection upper level L₁. Further, a detection wavelength λ of the detection target light in this case can be obtained by λ=hc/E₁.

In addition, the detection lower level L₀ in the absorption region 32, in general, substantially coincides with the valence band upper edge A₀ in the first well layer 351. Therefore, in FIG. 2, for the sake of simplicity, the detection lower level L₀ is illustrated by the valence band upper edge A₀. Further, in the calculation of the detection energy E₁ described above, an energy difference between the level in the valence band corresponding to the detection lower level L₀ and the valence band upper edge A₀ is ignored.

Further, in the configuration described above, the band gap energy E_{1g} is, for example, on the order of several hundred meV to eV.

Further, the energy difference E₁ₐ between the conduction band lower edge A₁ and the detection upper level L₁ is, for example, about several hundred meV.

Further, in the present embodiment, in the superlattice layer 30 included in the semiconductor layered structure illustrated in FIG. 1, the absorption region 32 including the first well layer 351 is located on the side of the semiconductor substrate 10 (the lower side in the diagram), and the relaxation region 33 including the n-th well layer is located on the side opposite to the semiconductor substrate 10 (the upper side). In the above configuration, the carrier block layer 11 provided so as to be adjacent to the absorption region 32 in the superlattice layer 30 has the function of preventing the electrons excited by the interband absorption in the absorption region 32 from moving to the region on the side opposite to the relaxation region 33.

Further, the n-type low refractive index layer 13 provided between the n-type contact layer 12 and the semiconductor substrate 10 on the side of the semiconductor substrate 10 with respect to the superlattice layer 30 functions as a cladding layer for confining the detection target light in the superlattice layer 30.

The effects of the interband photodetector 1A according to the present embodiment will be described.

In the interband photodetector 1A illustrated in FIG. 1 and FIG. 2, as the active layer for detecting the detection target light, the superlattice layer 30 including the unit layered structure 31 is used, in which the first barrier layer to the n-th barrier layer and the first well layer to the n-th well layer are alternately stacked, and which includes the absorption region 32 used for the absorption and the detection of the light and the relaxation region 33 used for the relaxation and the extraction of the electrons. In addition, the detection target light is detected by the interband absorption between the detection lower level L₀ in the valence band and the detection upper level L₁ in the conduction band in the absorption region 32, and the electrons are extracted by the relaxation via the m=n−1 relaxation levels L₂ to Lₙ in the relaxation region 33.

According to the above configuration, by using the interband electron transition instead of the intersubband electron transition in the conduction band for the detection of the detection target light, the detection wavelength of the light can be suitably set in a wide wavelength range by designing the band gap in the quantum well structure and the like. For example, in the interband photodetector 1A, it is possible to detect the light of a shorter wavelength compared with the quantum cascade detector using the intersubband electron transition.

Further, the band gap energy in the quantum well structure of the unit layered structure 31 constituting the superlattice layer 30, the energy of each of the detection upper level L₁ and the relaxation levels L₂ to Lₙ in the conduction band, and the like can be controlled by a layer thickness of each of the semiconductor layers constituting the unit layered structure 31, a composition of semiconductor materials, and the like. Therefore, the detection wavelength and the detection energy of the light in the photodetector 1A can be arbitrarily set by the design of the quantum well structure.

Further, as the quantum well structure in the unit layered structure 31 constituting the superlattice layer 30, as described above, the type-I quantum well structure is used in which the valence band upper edge in the quantum well layer is set higher than the valence band upper edge in the adjacent quantum barrier layer. As a result of the above, compared with the case of using the type-II quantum well structure, the degree of freedom in the selection of the semiconductor materials and in the design of the quantum well structure can be increased, and thus, the photodetector 1A can be suitably applied to the detection of the detection target light at a desired detection wavelength over a wide wavelength range.

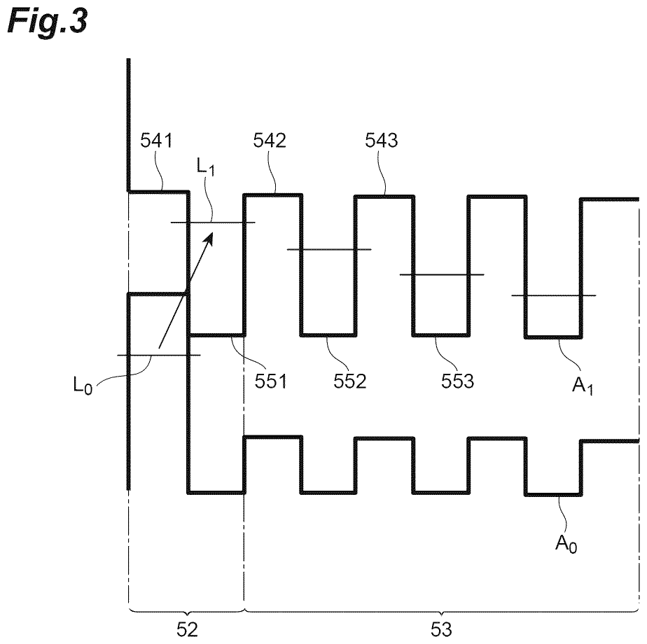

FIG. 3 is a diagram illustrating the type-II quantum well structure which is used in the conventional interband cascade detector (see Patent Document 2). In the configuration illustrated in FIG. 3, out of respective semiconductor layers constituting a superlattice layer, an absorption region 52 is formed by a first barrier layer 541 and a first well layer 551, and a relaxation region 53 is formed by respective semiconductor layers including a second barrier layer 542 and a second well layer 552.

Further, in the above configuration example, the superlattice layer used for the detection of the detection target light is configured to have the type-II quantum well structure in which the valence band upper edge in the quantum well layer is set lower than the valence band upper edge in the adjacent quantum barrier layer over the entire structure including the absorption region 52 and the relaxation region 53.

Further, as to the quantum well structure in the absorption region 52, the conduction band lower edge in the quantum well layer is set lower than the valence band upper edge in the adjacent quantum barrier layer. The above structure in the type-II structure is, in some cases, referred to as a type-III quantum well structure. In the type-II or type-III quantum well structure described above, the semiconductor materials which can be used in the structure are limited, and the degree of freedom in the design of the quantum well structure for the desired detection wavelength of the light is low.

On the other hand, in the interband photodetector 1A according to the above embodiment in which the type-I quantum well structure is used over the entire structure of the superlattice layer 30, there is no restriction on the usable semiconductor materials, and various semiconductor materials such as, for example, a nitride based material, a GaAs based material, and a InP based material can be used. Therefore, according to the interband photodetector 1A of the above configuration, it is possible to realize the photodetector capable of high-speed operation without applying bias over a wide wavelength range, for example, from a ultraviolet region (for example, a wavelength of 270 nm) to a near infrared region (for example, a wavelength of 2300 nm).

In the interband photodetector 1A of the above embodiment, it is preferable that, in the quantum well layer included in the absorption region 32, the detection upper level L₁ is a level arising from the ground level in the subband level structure of the conduction band. In a similar way, in each of the m quantum well layers included in the relaxation region 33, it is preferable that the relaxation level is a level arising from the ground level in the subband level structure of the conduction band.

As described above, by using the ground level, rather than an excited level, in the subband level structure in the conduction band for the light absorption and the electron relaxation, the level structure formed by the detection upper level L₁ and the m relaxation levels L₂ to Lₙ can be appropriately set, and the detection operation of the detection target light in the photodetector 1A by the interband light absorption in the absorption region 32 and the electron relaxation in the relaxation region 33 can be suitably realized.

In the interband photodetector 1A of the above embodiment, it is preferable that, in the unit layered structure 31, each of the n quantum barrier layers and the n quantum well layers is formed of an i-type semiconductor layer. As described above, by setting each of the quantum barrier layers and the quantum well layers included in the unit layered structure 31 of the superlattice layer 30 to the undoped i-type semiconductor layer, the detection of the detection target light using the interband absorption can be suitably realized.

In addition, in the quantum cascade detector using the intersubband electron transition in the conduction band, a semiconductor layer doped with n-type impurity is used in a part of the quantum well layers in order to fill a base subband with charges. On the other hand, in the interband photodetector 1A using the interband electron transition, it is not necessary to fill the subband with the charges, and further, by using the i-type semiconductor layer as each of the semiconductor layers of the superlattice layer 30 as described above, the detection efficiency of the light by the photodetector 1A can be improved.

In the above embodiment, as to the number of units of the unit layered structure 31 in the superlattice layer 30, the superlattice layer 30 is configured to include only the single unit layered structure 31. As to the configuration of the superlattice layer 30 described above, the superlattice layer 30 may also be configured to include a plurality of unit layered structures 31, each including the absorption region 32 and the relaxation region 33. As described above, in the case in which the superlattice layer 30 has a cascade structure in which the plurality of unit layered structures 31 are stacked in multiple stages, the photodetector 1A described above functions as an interband cascade detector. In this case, by using the cascade structure of the plurality of unit layered structures 31, the detection efficiency of the light by the photodetector 1A can be improved.

In the interband photodetector 1A of the above embodiment, as illustrated in FIG. 2, in the unit layered structure 31, the absorption region 32 is configured to include the single quantum well layer 351.

Further, the absorption region 32 in the unit layered structure 31 may also be configured to include a plurality of quantum well layers, as will be described later.

As described above, the quantum well layer included in the absorption region 32 and functioning as the absorption well layer may be configured by the single quantum well layer or the plurality of quantum well layers. In the case in which the absorption region 32 is formed by the single quantum well layer, the configuration of the absorption region 32 can be simplified. Further, in the case in which the absorption region 32 is formed by the plurality of quantum well layers, the detection efficiency of the light by the interband absorption can be improved.

As to an energy configuration of the valence band, the conduction band, and the respective levels used for the light absorption and the electron relaxation in the interband photodetector 1A, it is preferable that the band gap energy in each of the quantum well layers included in the relaxation region 33 is set to be larger than the band gap energy in the quantum well layer included in the absorption region 32.

Further, it is preferable that the energy difference between the level in the valence band and the relaxation level in each of the quantum well layers included in the relaxation region 33 is set to be larger than the energy difference between the detection lower level L₀ and the detection upper level L₁ in the quantum well layer included in the absorption region 32. Further, in this case, the energy difference between the level in the valence band and the relaxation level in each of the quantum well layers included in the relaxation region 33 may also be set to be larger than the detection energy of the detection target light.

By using the energy configuration described above, by setting the band gap energy in the relaxation region 33 or the energy difference between the level in the valence band and the relaxation level to be sufficiently large, the occurrence of unnecessary light absorption in the relaxation region 33 can be suppressed, so that the light absorption occurs only in the absorption region 32. As a result of the above, the detection operation of the light by the interband light absorption in the absorption region 32 and the electron relaxation in the relaxation region 33 can be suitably realized, thereby making it possible to improve the detection efficiency of the light by the photodetector 1A.

In addition, in the case in which the level in the valence band substantially coincides with the valence band upper edge A₀, the energy difference between the level in the valence band and the relaxation level in each of the quantum well layers included in the relaxation region 33 can be obtained by the sum of the band gap energy corresponding to the energy difference between the valence band upper edge A₀ and the conduction band lower edge A₁, and the energy difference between the conduction band lower edge A₁ and the relaxation level. Further, the above configuration can be realized, for example, by making the semiconductor material or the composition of the quantum well layer in the absorption region 32 different from the semiconductor material or the composition of the quantum well layer in the relaxation region 33.

In the interband photodetector 1A of the above embodiment, it is preferable that, in the absorption region 32, the energy difference between the detection lower level L₀ and the detection upper level L₁ is set to be larger than an energy of a longitudinal optical (LO) phonon. Further, it is preferable that, in the relaxation region 33, the energy difference between the adjacent relaxation levels out of the m relaxation levels is set to be larger than the energy of the LO phonon.

According to each of the above configurations, in the relaxation level structure of the electrons formed by the m relaxation levels in the relaxation region 33, the high-speed relaxation of the electrons by the LO phonon scattering can be used. In this case, the electrons excited to the detection upper level L₁ by the light absorption move to the relaxation level L₂ in the relaxation region 33 by the resonant tunneling effect, and further, in the relaxation level structure formed by the relaxation levels L₂ to Lₙ, the electrons are rapidly extracted by the relaxation process including the high-speed relaxation due to the LO phonon scattering.

In the interband photodetector 1A of the above embodiment, as illustrated in FIG. 1, corresponding to the configuration in which the absorption region 32 in the superlattice layer 30 is located on the side of the semiconductor substrate 10, the carrier block layer 11 is provided in the region on the side of the semiconductor substrate 10 with respect to the superlattice layer 30. According to the above configuration, by the carrier block layer 11, the electrons excited by the interband absorption in the absorption region 32 are prevented from moving to the region on the side opposite to the relaxation region 33, thereby making it possible to improve the extraction efficiency of the electrons by using the m relaxation levels in the relaxation region 33.

In addition, contrary to the above configuration, in the case in which the absorption region 32 in the superlattice layer 30 is located on the side opposite to the semiconductor substrate 10, the carrier block layer may be provided in the region on the side opposite to the semiconductor substrate 10 with respect to the superlattice layer 30. In general, it is preferable that the carrier block layer is provided in the region adjacent to the absorption region 32, the adjacent region selected from the region on the side of the semiconductor substrate 10 with respect to the superlattice layer 30 and the region on the side opposite to the semiconductor substrate 10 with respect to the superlattice layer 30.

Further, a p-type semiconductor layer may be provided in place of the carrier block layer. In this case, it is preferable that the p-type semiconductor layer is provided in the region adjacent to the absorption region 32, selected from the region on the side of the semiconductor substrate 10 with respect to the superlattice layer 30 and the region on the side opposite to the semiconductor substrate 10 with respect to the superlattice layer 30. Further, in this case, as the p-type semiconductor layer, specifically, a p-type contact layer or a p-type low refractive index layer can be used, as will be described later.

In the interband photodetector 1A of the above embodiment, as illustrated in FIG. 1, the low refractive index layer 13 having a lower refractive index than the superlattice layer 30 is provided in the region on the side of the semiconductor substrate 10 with respect to the superlattice layer 30. Further, in the photodetector 1A, a configuration may also be used in which the low refractive index layer is provided in the region on the side opposite to the semiconductor substrate 10 with respect to the superlattice layer 30.

As described above, by providing the low refractive index layer functioning as the cladding layer for the superlattice layer 30 in at least one of the region on the side of the semiconductor substrate 10 with respect to the superlattice layer 30 and the region on the side opposite to the semiconductor substrate 10 with respect to the superlattice layer 30, the detection target light can be confined in the superlattice layer 30, thereby making it possible to improve the detection efficiency of the light by the photodetector 1A.

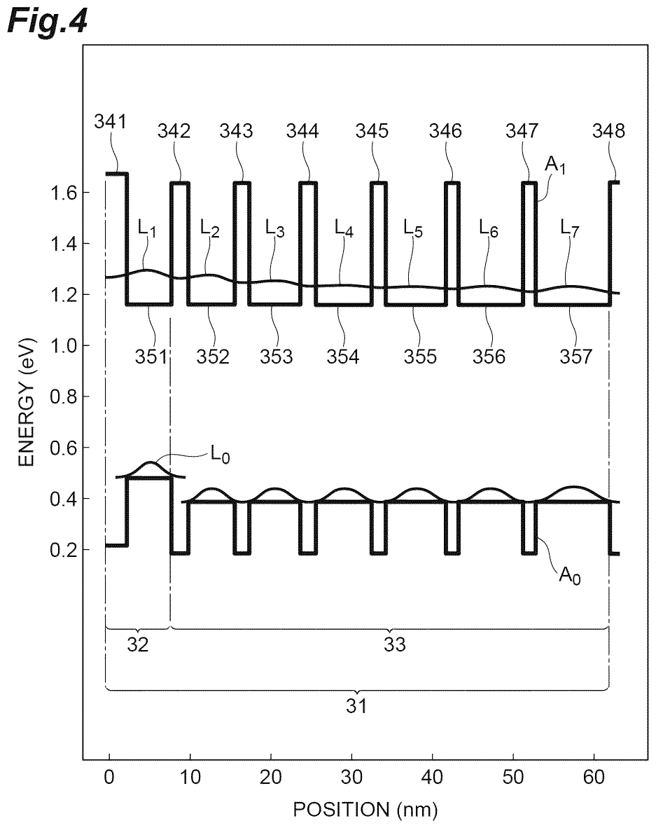

The configuration of the interband photodetector 1A according to the present embodiment will be described together with a specific example of the element structure including the quantum well structure in the superlattice layer 30. In this case, as to the entire semiconductor layered structure in the interband photodetector 1A, the configuration illustrated in FIG. 1 is used. Further, FIG. 4 is a graph illustrating the specific example of the configuration of the unit layered structure 31 constituting the superlattice layer 30. In the graph of FIG. 4, the horizontal axis indicates the position (nm) in the semiconductor stacking direction, and the vertical axis indicates the energy (eV).

In the quantum well structure of the superlattice layer 30 in the present configuration example, an example designed for the detection wavelength of the light of 1550 nm is illustrated. In FIG. 4, it is assumed that the superlattice layer 30 includes the single unit layered structure 31, and the quantum well structure, the valence band upper edge A₀, the conduction band lower edge A₁, and the level structure in the absorption region 32 and relaxation region 33 of the unit layered structure 31 are illustrated. Further, the element structure illustrated in FIG. 1 and FIG. 4 can be formed by crystal growth using, for example, the molecular beam epitaxy (MBE) method or the metal organic vapor phase epitaxy (MOVPE) method.

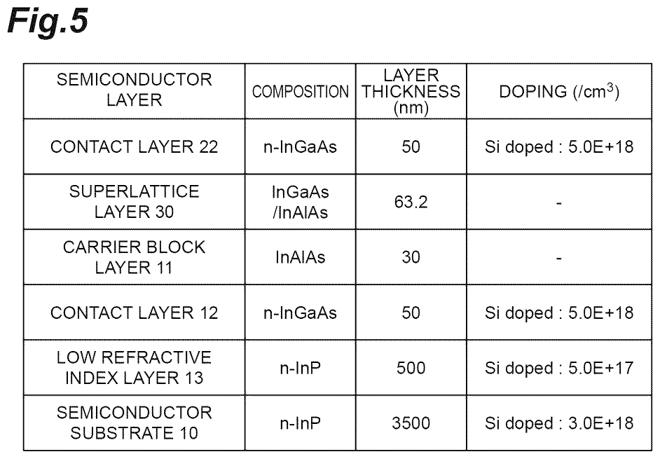

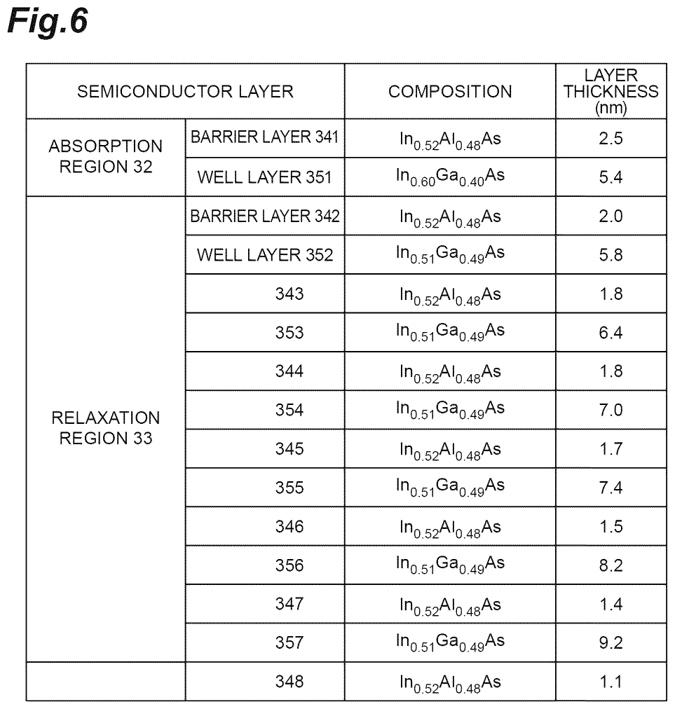

FIG. 5 is a table showing the specific example of the semiconductor layered structure in the interband photodetector 1A illustrated in FIG. 1. Further, FIG. 6 is a table showing the specific example of the layered structure in the superlattice layer 30 of the interband photodetector 1A illustrated in FIG. 1. The layered structure shown in FIG. 6 corresponds to the quantum well structure illustrated in the graph of FIG. 4.

In the semiconductor layered structure of the interband photodetector 1A according to the present configuration example, in the configuration illustrated in FIG. 1, as the semiconductor substrate 10, as shown in FIG. 5, an n-type InP substrate with a thickness of 3500 nm is used. In addition, on the InP substrate 10, in order from the substrate 10 side, an n-type InP low refractive index layer 13 with a thickness of 500 nm, an n-type InGaAs contact layer 12 with a thickness of 50 nm, an InAlAs carrier block layer 11 with a thickness of 30 nm, a superlattice layer 30 including a single unit layered structure 31, and an n-type InGaAs contact layer 22 with a thickness of 50 nm are stacked, thereby forming the element structure of the interband photodetector 1A.

As shown in FIG. 4 and FIG. 6, the unit layered structure 31 of the superlattice layer 30 in the present configuration example is configured as a quantum well structure in which seven quantum barrier layers 341 to 347 and seven quantum well layers 351 to 357 are alternately stacked. Further, in the present configuration example, an additional quantum barrier layer 348 is provided outside the quantum well layer 357.

Out of the respective semiconductor layers of the unit layered structure 31, each of the quantum barrier layers 341 to 348 is formed of an In_{0.52}Al_{0.84}As layer. Further, each of the quantum well layers 352 to 357 is formed of an In_{0.51}Ga_{0.49}As layer. Further, the quantum well layer 351 is formed of an In_{0.60}Ga_{0.40}As layer having a different composition ratio from the other quantum well layers.

Thus, the superlattice layer 30 in the present configuration example is configured by an InGaAs/InAlAs quantum well structure. In addition, the respective layer thicknesses of the quantum barrier layers and the quantum well layers are as shown in FIG. 6. Further, in FIG. 5, as the layer thickness of the superlattice layer 30, the layer thickness including the additional quantum barrier layer 348 is shown.

In the unit layered structure 31 described above, the first barrier layer 341 and the first well layer 351 constitute the absorption region 32 used for the absorption and the detection of the light. Further, the second to seventh barrier layers 342 to 347 and the second to seventh well layers 352 to 357 constitute the relaxation region 33 used for the relaxation and the extraction of the electrons. Each of the above semiconductor layers is formed of the i-type semiconductor layer. Further, in the present configuration example, in the superlattice layer 30, the absorption region 32 is located on the side of the semiconductor substrate 10, and the relaxation region 33 is located on the side opposite to the semiconductor substrate 10.

In the above configuration, the unit layered structure 31 has, in its level structure illustrated in FIG. 4, the detection lower level L₀ and the detection upper level L₁ in the absorption region 32 described above with reference to FIG. 2, and the relaxation levels L₂ to L₇ constituting the relaxation level structure in the relaxation region 33. In addition, by using the above level structure, the detection operation of the light by the interband light absorption in the absorption region 32 and the electron relaxation in the relaxation region 33 as described above is realized.

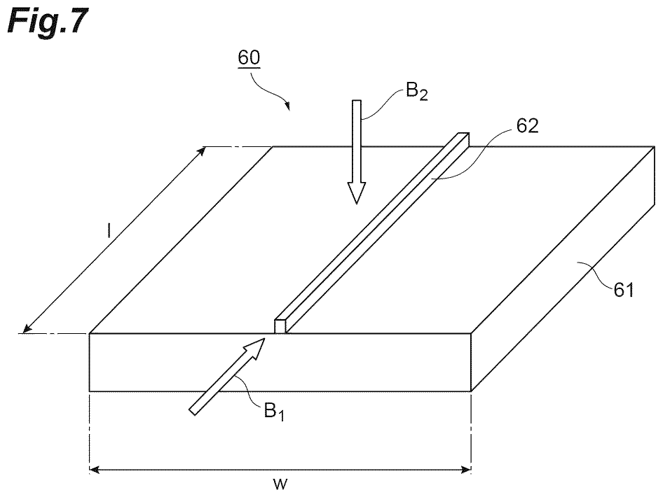

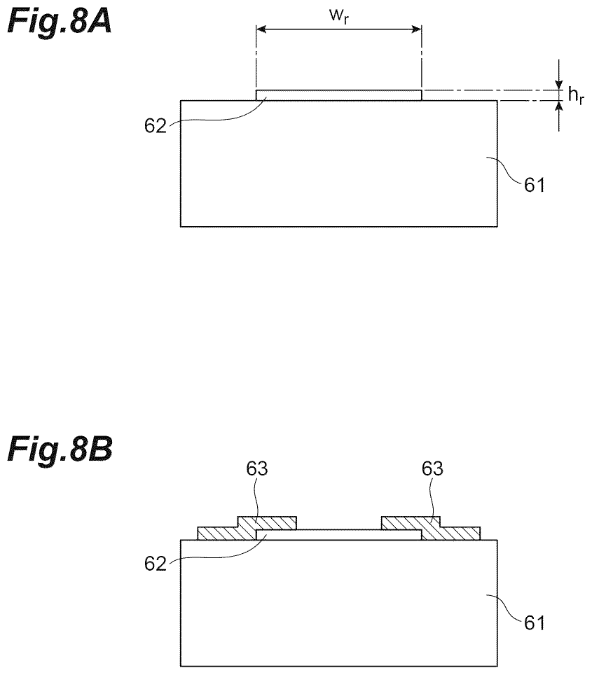

A photodetection element was prepared for the interband photodetector 1A having the configuration illustrated in FIG. 1, FIG. 2, and FIG. 4 to FIG. 6, and a measurement was performed for the detection operation of the light. FIG. 7, FIG. 8A and FIG. 8B are diagrams schematically illustrating an example of a configuration of a photodetection element 60 using the interband photodetector 1A, and FIG. 7 is a perspective view, and each of FIG. 8A and FIG. 8B is a side view.

As illustrated in FIG. 7 and FIG. 8A, the photodetection element 60 has a configuration in which a ridge portion 62 including the superlattice layer 30 is formed on a base portion 61 including the semiconductor substrate 10. An element width of the base portion 61 is set to w=500 μm, and an element length is set to 1=500 μm. Further, for the ridge portion 62, a ridge width is set to wᵣ=50 μm, a ridge length is set to 1=500 μm, and a ridge height is set to hᵣ=1.5 to 1.8 μm.

Further, as a light source for supplying the detection target light, a benchtop type and a fiber output type wavelength variable laser light source (manufactured by THORLABS, TLX1) was used. The wavelength of the detection target light is set to 1528 to 1566 nm, and the output is set to 8 mW. Further, as indicated by an arrow B₁ in FIG. 7, the detection target light is incident on the photodetection element 60 from an element side surface.

In addition, as indicated by an arrow B₂ in FIG. 7, in the case in which the detection target light is incident on the photodetection element 60 from an element upper surface, as illustrated in FIG. 8B, an opening portion is formed in a metal electrode 63 formed on the element upper surface, and a configuration is used in which the detection target light is incident through the opening portion.

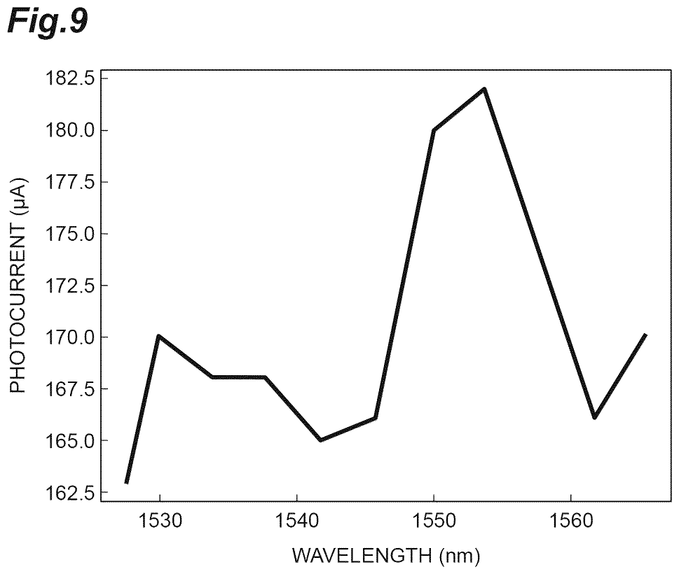

FIG. 9 is a graph showing a photodetection spectrum acquired by the photodetection element 60 using the interband photodetector 1A illustrated in FIG. 7, FIG. 8A and FIG. 8B. In the graph of FIG. 9, the horizontal axis indicates the wavelength (nm) of the light, and the vertical axis indicates the photocurrent (μA) output from the photodetector 1A. As shown in the graph, it is confirmed that the detection target light is detected by using the interband photodetector 1A of the above configuration.

The quantum well structure and the level structure in the superlattice layer 30 of the interband photodetector 1A will be further described.

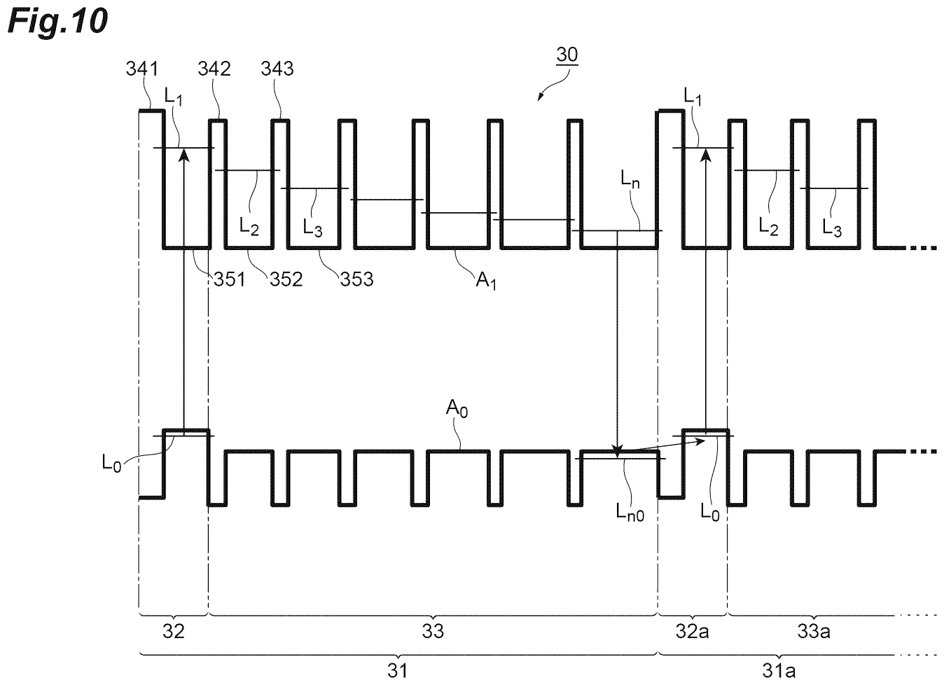

FIG. 10 is a diagram illustrating a first modification of the quantum well structure and the level structure in the superlattice layer 30 included in the interband photodetector 1A. In the configuration illustrated in FIG. 10, the configuration of the unit layered structure 31 in the superlattice layer 30 is the same as the configuration illustrated in FIG. 2, and in addition, in the present modification, the superlattice layer 30 is configured to include a plurality of unit layered structures 31. In FIG. 10, out of the plurality of unit layered structures 31, the unit layered structure 31 including the absorption region 32 and the relaxation region 33, and a unit layered structure 31a including an absorption region 32a adjacent to the relaxation region 33 and a relaxation region 33a are illustrated.

In the above configuration, the superlattice layer 30 in the photodetector 1A detects the detection target light incident on the photodetector 1A by the interband absorption from the detection lower level L₀ to the detection upper level L₁ in the absorption region 32. In addition, the electrons excited by the interband absorption are relaxed via the relaxation level structure formed by the relaxation levels L₂ to Lₙ in the relaxation region 33.

The electrons relaxed to the relaxation level Lₙ in the n-th well layer move from the relaxation level Lₙ in the conduction band to a level Lₙ₀ in the valence band by electron recombination, and further, move to the detection lower level L₀ in the absorption region 32a of the adjacent unit layered structure 31a by the resonant tunneling effect. In addition, in the unit layered structure 31a, as in the unit layered structure 31, the detection operation of the light by the light absorption and the electron relaxation is performed.

As described above, by configuring the photodetector 1A as the interband cascade detector in which the plurality of unit layered structures 31 are stacked in multiple stages in the superlattice layer 30, the detection efficiency of the light by the photodetector 1A can be improved.

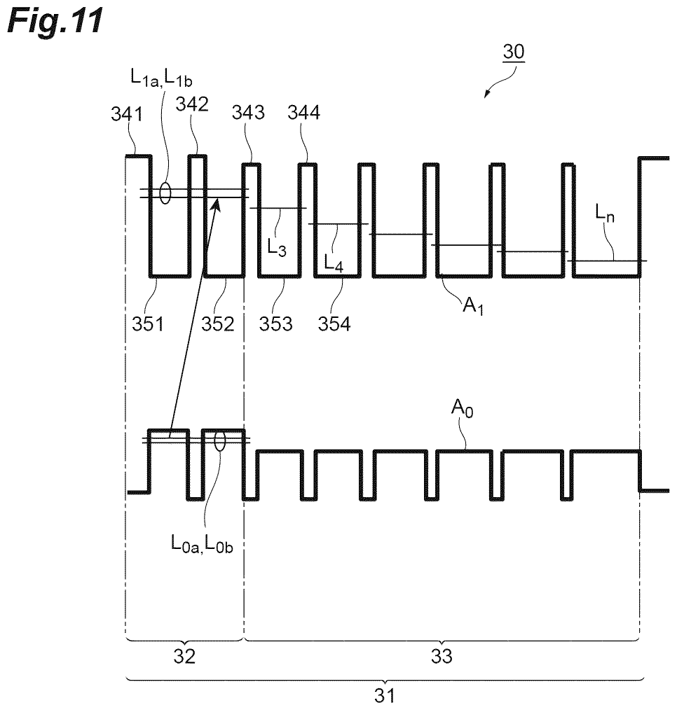

FIG. 11 is a diagram illustrating a second modification of the quantum well structure and the level structure in the superlattice layer 30 included in the interband photodetector 1A. In the configuration illustrated in FIG. 11, the absorption region 32 is configured to include, as two quantum well layers, the first well layer 351 and the second well layer 352. Further, the relaxation region 33 is configured to include, as m=n−2 quantum well layers, the third well layer 353 to the n-th well layer.

The absorption region 32 has, in its level structure, two detection lower levels L₀ₐ and L_{0b} arising from levels in the valence band in the first well layer 351 and the second well layer 352 included in the absorption region 32 and functioning as the absorption well layers, and two detection upper levels L₁ₐ and L_{1b} arising from levels in the conduction band. Further, the relaxation region 33 has, in its level structure, n−2 relaxation levels L₃ to Lₙ each arising from a level in the conduction band in each of the third well layer 353 to the n-th well layer included in the relaxation region 33.

As described above, the absorption region 32 in the unit layered structure 31 of the superlattice layer 30 may be configured to include two or more quantum well layers. In the above configuration, the detection efficiency of the light by the interband absorption can be improved.

The basic configuration of the interband photodetector and the semiconductor layered structure of the photodetector will be further described.

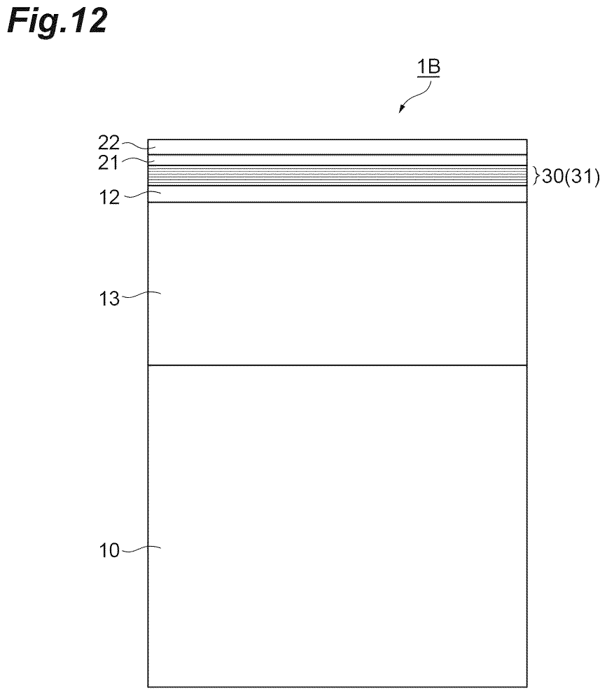

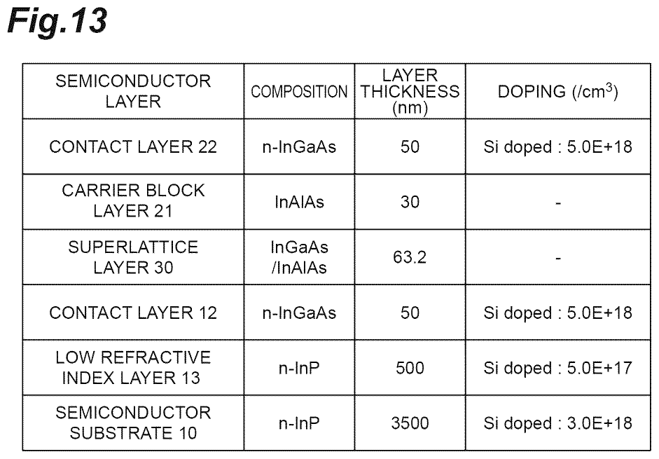

FIG. 12 is a diagram illustrating a basic configuration of a second embodiment of the interband photodetector in the form of the semiconductor layered structure. Further, FIG. 13 is a table showing a specific example of the semiconductor layered structure in the interband photodetector illustrated in FIG. 12.

In the interband photodetector 1B according to the present configuration example, in the semiconductor layered structure, an n-type InP substrate 10 with a thickness of 3500 nm is used as the semiconductor substrate. In addition, on the InP substrate 10, in order from the substrate 10 side, an n-type InP low refractive index layer 13 with a thickness of 500 nm, an n-type InGaAs contact layer 12 with a thickness of 50 nm, the superlattice layer 30 including the unit layered structure 31, an InAlAs carrier block layer 21 with a thickness of 30 nm, and an n-type InGaAs contact layer 22 with a thickness of 50 nm are stacked.

Further, in the present configuration example, in the unit layered structure 31 of the superlattice layer 30, the absorption region 32 is located on the side opposite to the semiconductor substrate 10, and the relaxation region 33 is located on the side of the semiconductor substrate 10. In the above configuration, the carrier block layer 21 provided so as to be adjacent to the absorption region 32 has the function of preventing the electrons excited by the interband absorption in the absorption region 32 from moving to the region on the side opposite to the relaxation region 33.

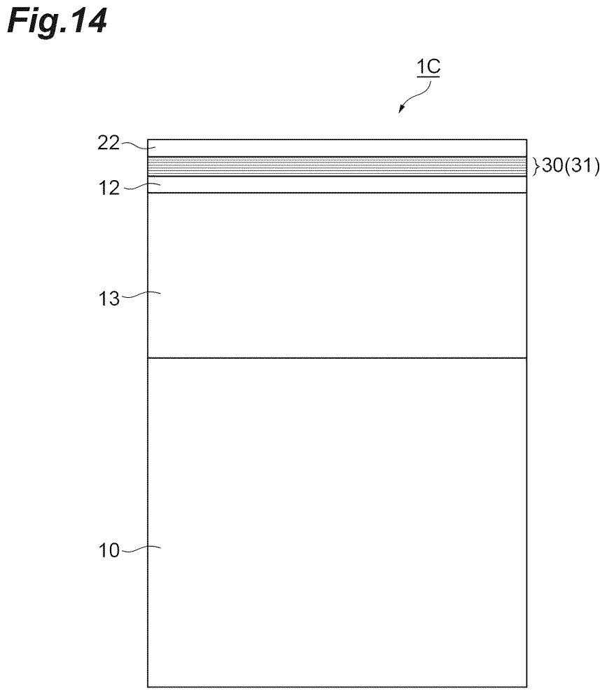

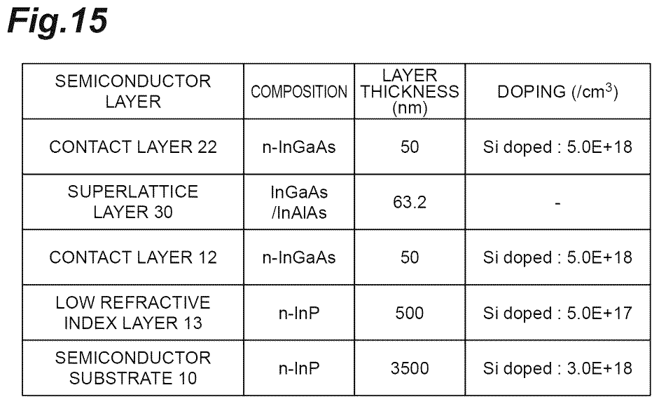

FIG. 14 is a diagram illustrating a basic configuration of a third embodiment of the interband photodetector in the form of the semiconductor layered structure. Further, FIG. 15 is a table showing a specific example of the semiconductor layered structure in the interband photodetector illustrated in FIG. 14.

In the interband photodetector 1C according to the present configuration example, in the semiconductor layered structure, an n-type InP substrate 10 with a thickness of 3500 nm is used as the semiconductor substrate. In addition, on the InP substrate 10, in order from the substrate 10 side, an n-type InP low refractive index layer 13 with a thickness of 500 nm, an n-type InGaAs contact layer 12 with a thickness of 50 nm, the superlattice layer 30 including the unit layered structure 31, and an n-type InGaAs contact layer 22 with a thickness of 50 nm are stacked.

In the present configuration example, the carrier block layer is not provided for the superlattice layer 30. Even in the case of the above configuration, the photodetector 1C can realize the detection operation of the light. Further, in the above configuration, the semiconductor layered structure is simplified, and thus, it becomes easy to form the photodetector 1C by crystal growth. In addition, in the present configuration example, in the unit layered structure 31 of the superlattice layer 30, the absorption region 32 may be located on the side of the semiconductor substrate 10, or may be located on the side opposite to the semiconductor substrate 10.

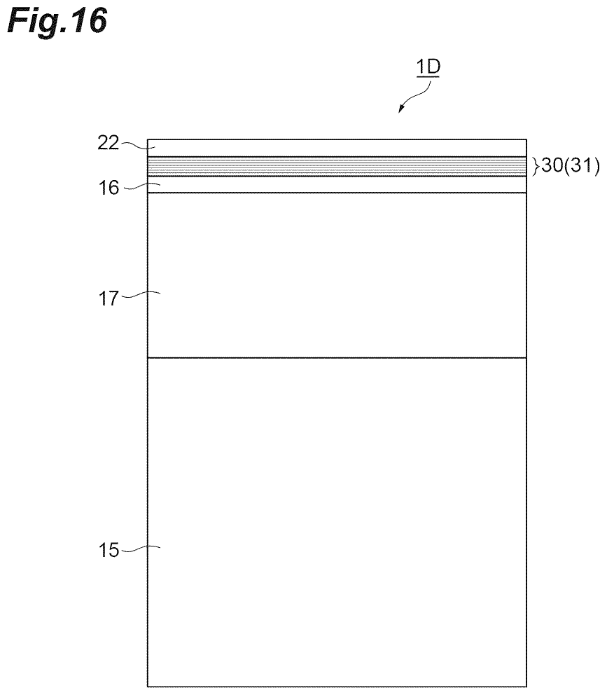

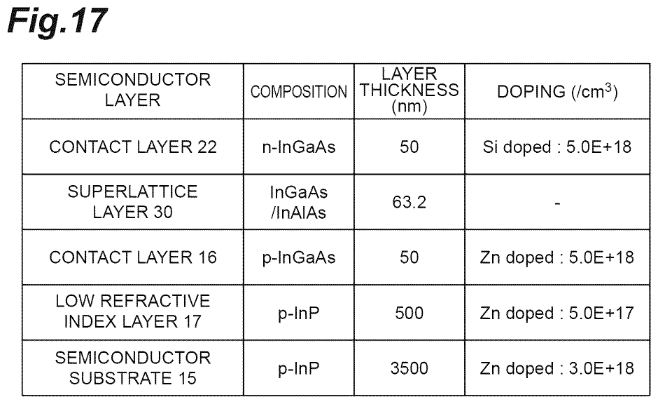

FIG. 16 is a diagram illustrating a basic configuration of a fourth embodiment of the interband photodetector in the form of the semiconductor layered structure. Further, FIG. 17 is a table showing a specific example of the semiconductor layered structure in the interband photodetector illustrated in FIG. 16.

In the interband photodetector 1D according to the present configuration example, in the semiconductor layered structure, a p-type InP substrate 15 with a thickness of 3500 nm is used as the semiconductor substrate. In addition, on the InP substrate 15, in order from the substrate 15 side, a p-type InP low refractive index layer 17 with a thickness of 500 nm, a p-type InGaAs contact layer 16 with a thickness of 50 nm, the superlattice layer 30 including the unit layered structure 31, and an n-type InGaAs contact layer 22 with a thickness of 50 nm are stacked.

Further, in the present configuration example, in the unit layered structure 31 of the superlattice layer 30, the absorption region 32 is located on the side of the semiconductor substrate 15. In the above configuration, a depletion layer is formed at an interface between the superlattice layer 30 and the p-type contact layer 16 which is the p-type semiconductor layer, and the depletion layer has the function of, in a similar way to the carrier block layer, preventing the electrons excited by the interband absorption in the absorption region 32 from moving to the region on the side opposite to the relaxation region 33.

In addition, in the configuration illustrated in FIG. 16 and FIG. 17, in the unit layered structure 31 of the superlattice layer 30, the absorption region 32 may be located on the side opposite to the semiconductor substrate. In this case, it is preferable that each of the semiconductor substrate, the low refractive index layer, and the contact layer provided below the superlattice layer 30 is set to the n-type semiconductor layer, and the contact layer provided above the superlattice layer 30 is set to the p-type semiconductor layer.

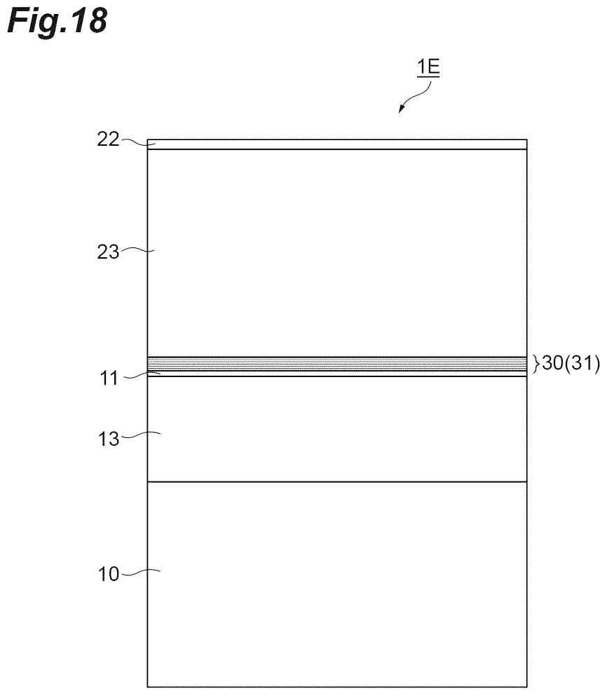

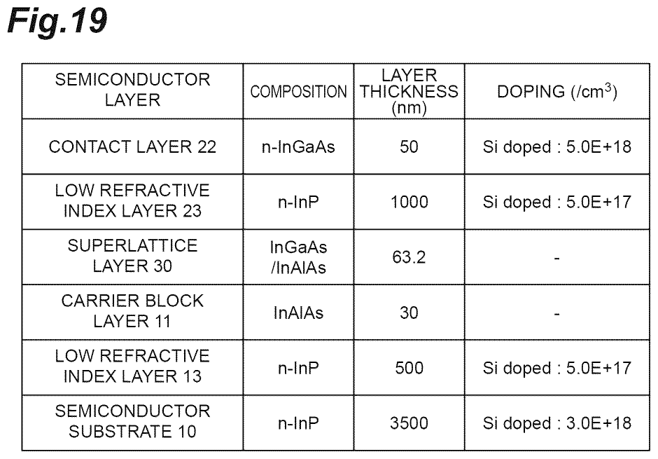

FIG. 18 is a diagram illustrating a basic configuration of a fifth embodiment of the interband photodetector in the form of the semiconductor layered structure. Further, FIG. 19 is a table showing a specific example of the semiconductor layered structure in the interband photodetector illustrated in FIG. 18.

In the interband photodetector 1E according to the present configuration example, in the semiconductor layered structure, an n-type InP substrate 10 with a thickness of 3500 nm is used as the semiconductor substrate. In addition, on the InP substrate 10, in order from the substrate 10 side, an n-type InP low refractive index layer 13 with a thickness of 500 nm, an InAlAs carrier block layer 11 with a thickness of 30 nm, the superlattice layer 30 including the unit layered structure 31, an n-type InP low refractive index layer 23 with a thickness of 1000 nm, and an n-type InGaAs contact layer 22 with a thickness of 50 nm are stacked.

Further, in the present configuration example, in the unit layered structure 31 of the superlattice layer 30, the absorption region 32 is located on the side of the semiconductor substrate 10. In the above configuration, the carrier block layer 11 has the function of preventing the electrons excited by the interband absorption in the absorption region 32 from moving to the region on the side opposite to the relaxation region 33.

Further, in the present configuration example, the n-type low refractive index layers 13 and 23 are provided respectively on the side of the semiconductor substrate 10 and on the side opposite to the semiconductor substrate 10 with respect to the superlattice layer 30. As described above, by using the configuration in which the superlattice layer 30 is sandwiched between the low refractive index layers 13 and 23, the detection target light can be reliably confined in the superlattice layer 30, thereby making it possible to improve the detection efficiency of the light by the photodetector 1E.

In addition, in the configuration illustrated in FIG. 18 and FIG. 19, in the unit layered structure 31 of the superlattice layer 30, the absorption region 32 may be located on the side opposite to the semiconductor substrate 10. In this case, it is preferable that the carrier block layer is provided between the superlattice layer 30 and the n-type low refractive index layer 23. Further, it is also possible to use the configuration in which the carrier block layer is not provided. In this case, in the unit layered structure 31 of the superlattice layer 30, the absorption region 32 may be located on the side of the semiconductor substrate 10, or may be located on the side opposite to the semiconductor substrate 10.

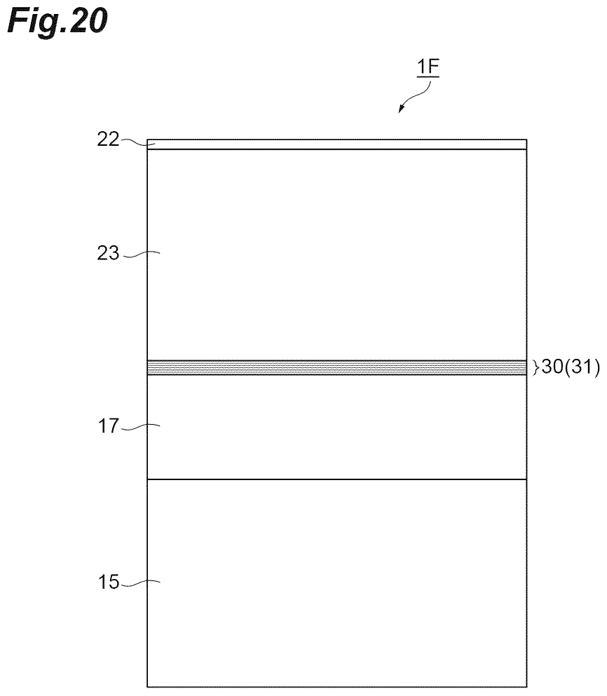

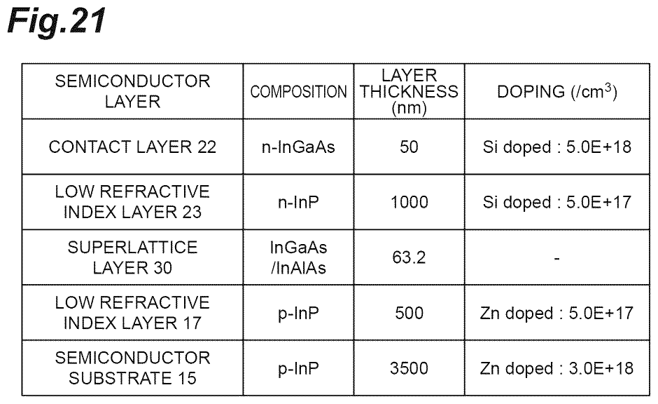

FIG. 20 is a diagram illustrating a basic configuration of a sixth embodiment of the interband photodetector in the form of the semiconductor layered structure. Further, FIG. 21 is a table showing a specific example of the semiconductor layered structure in the interband photodetector illustrated in FIG. 20.

In the interband photodetector 1F according to the present configuration example, in the semiconductor layered structure, a p-type InP substrate 15 with a thickness of 3500 nm is used as the semiconductor substrate. In addition, on the InP substrate 15, in order from the substrate 15 side, a p-type InP low refractive index layer 17 with a thickness of 500 nm, the superlattice layer 30 including the unit layered structure 31, an n-type InP low refractive index layer 23 with a thickness of 1000 nm, and an n-type InGaAs contact layer 22 with a thickness of 50 nm are stacked.

Further, in the present configuration example, in the unit layered structure 31 of the superlattice layer 30, the absorption region 32 is located on the side of the semiconductor substrate 15. In the above configuration, a depletion layer, which is formed at an interface between the superlattice layer 30 and the p-type low refractive index layer 17 which is the p-type semiconductor layer, has the function of preventing the electrons excited by the interband absorption in the absorption region 32 from moving to the region on the side opposite to the relaxation region 33.

Further, in the present configuration example, the p-type low refractive index layer 17 and the n-type low refractive index layer 23 are provided respectively on the side of the semiconductor substrate 15 and on the side opposite to the semiconductor substrate 15 with respect to the superlattice layer 30. As described above, by using the configuration in which the superlattice layer 30 is sandwiched between the low refractive index layers 17 and 23, the detection target light can be reliably confined in the superlattice layer 30, thereby making it possible to improve the detection efficiency of the light by the photodetector 1F.

In addition, in the configuration illustrated in FIG. 20 and FIG. 21, in the unit layered structure 31 of the superlattice layer 30, the absorption region 32 may be located on the side opposite to the semiconductor substrate. In this case, it is preferable that each of the semiconductor substrate and the low refractive index layer provided below the superlattice layer 30 is set to the n-type semiconductor layer, and each of the low refractive index layer and the contact layer provided above the superlattice layer 30 is set to the p-type semiconductor layer.

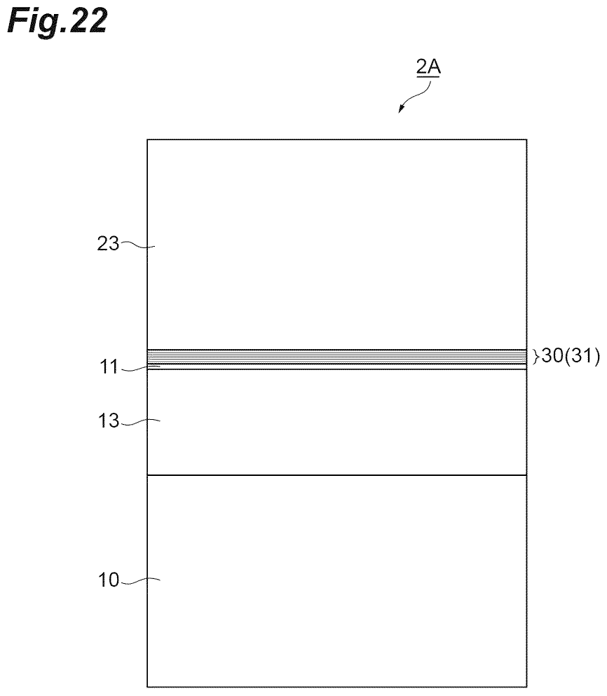

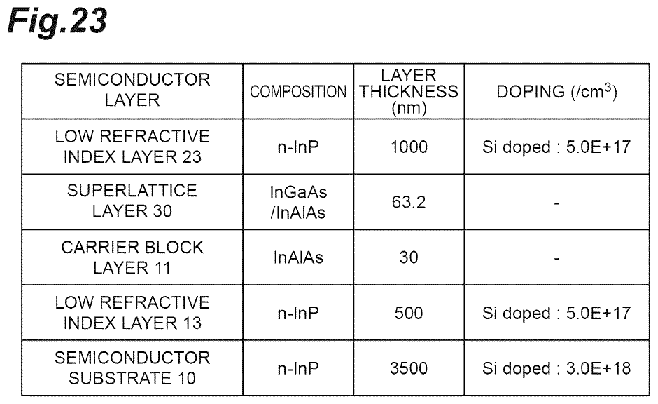

FIG. 22 is a diagram illustrating a basic configuration of a seventh embodiment of the interband photodetector in the form of the semiconductor layered structure. Further, FIG. 23 is a table showing a specific example of the semiconductor layered structure in the interband photodetector illustrated in FIG. 22.

In the interband photodetector 2A according to the present configuration example, in the semiconductor layered structure, an n-type InP substrate 10 with a thickness of 3500 nm is used as the semiconductor substrate. In addition, on the InP substrate 10, in order from the substrate 10 side, an n-type InP low refractive index layer 13 with a thickness of 500 nm, an InAlAs carrier block layer 11 with a thickness of 30 nm, the superlattice layer 30 including the unit layered structure 31, and an n-type InP low refractive index layer 23 with a thickness of 1000 nm are stacked.

Further, in the present configuration example, in the unit layered structure 31 of the superlattice layer 30, the absorption region 32 is located on the side of the semiconductor substrate 10. In the above configuration, the carrier block layer 11 has the function of preventing the electrons excited by the interband absorption in the absorption region 32 from moving to the region on the side opposite to the relaxation region 33.

Further, in the present configuration example, the n-type low refractive index layers 13 and 23 are provided respectively on the side of the semiconductor substrate 10 and on the side opposite to the semiconductor substrate 10 with respect to the superlattice layer 30. As described above, by using the configuration in which the superlattice layer 30 is sandwiched between the low refractive index layers 13 and 23, the detection target light can be reliably confined in the superlattice layer 30, thereby making it possible to improve the detection efficiency of the light by the photodetector 2A.

Further, in the present configuration example, the n-type contact layer is not formed above the n-type low refractive index layer 23, and the n-type low refractive index layer 23 is used as the n-type contact layer. In the above configuration, the occurrence of absorption of the detection target light by the contact layer can be suppressed.

In addition, in the configuration illustrated in FIG. 22 and FIG. 23, in the unit layered structure 31 of the superlattice layer 30, the absorption region 32 may be located on the side opposite to the semiconductor substrate 10. In this case, it is preferable that the carrier block layer is provided between the superlattice layer 30 and the n-type low refractive index layer 23. Further, it is also possible to use the configuration in which the carrier block layer is not provided. In this case, in the unit layered structure 31 of the superlattice layer 30, the absorption region 32 may be located on the side of the semiconductor substrate 10, or may be located on the side opposite to the semiconductor substrate 10.

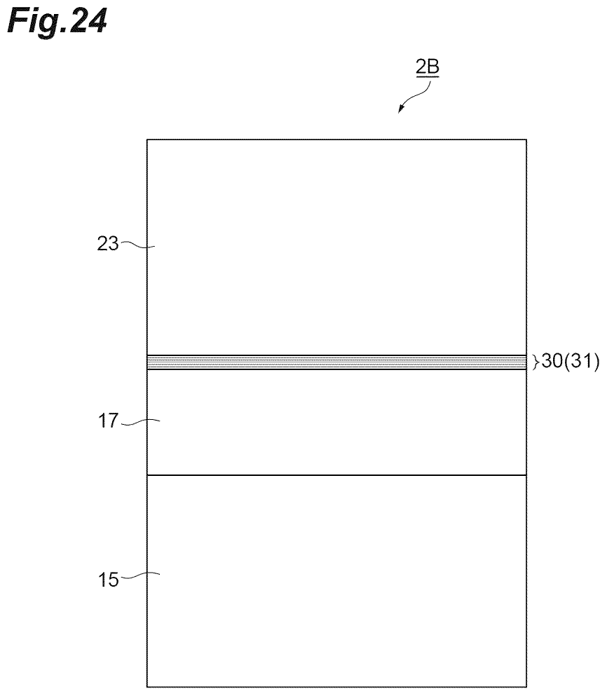

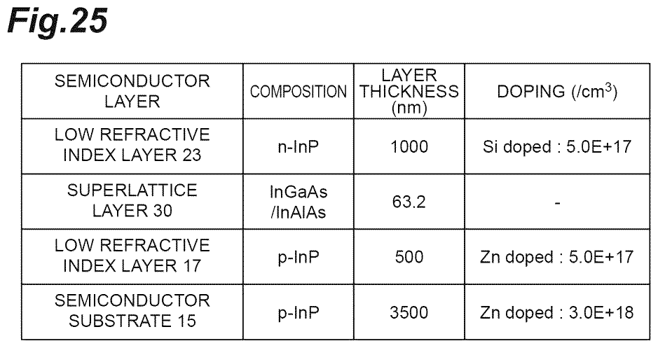

FIG. 24 is a diagram illustrating a basic configuration of an eighth embodiment of the interband photodetector in the form of the semiconductor layered structure. Further, FIG. 25 is a table showing a specific example of the semiconductor layered structure in the interband photodetector illustrated in FIG. 24.

In the interband photodetector 2B according to the present configuration example, in the semiconductor layered structure, a p-type InP substrate 15 with a thickness of 3500 nm is used as the semiconductor substrate. In addition, on the InP substrate 15, in order from the substrate 15 side, a p-type InP low refractive index layer 17 with a thickness of 500 nm, the superlattice layer 30 including the unit layered structure 31, and an n-type InP low refractive index layer 23 with a thickness of 1000 nm are stacked.

Further, in the present configuration example, in the unit layered structure 31 of the superlattice layer 30, the absorption region 32 is located on the side of the semiconductor substrate 15. In the above configuration, a depletion layer, which is formed at an interface between the superlattice layer 30 and the p-type low refractive index layer 17 which is the p-type semiconductor layer, has the function of preventing the electrons excited by the interband absorption in the absorption region 32 from moving to the region on the side opposite to the relaxation region 33.

Further, in the present configuration example, the p-type low refractive index layer 17 and the n-type low refractive index layer 23 are provided respectively on the side of the semiconductor substrate 15 and on the side opposite to the semiconductor substrate 15 with respect to the superlattice layer 30. As described above, by using the configuration in which the superlattice layer 30 is sandwiched between the low refractive index layers 17 and 23, the detection target light can be reliably confined in the superlattice layer 30, thereby making it possible to improve the detection efficiency of the light by the photodetector 2B.

Further, in the present configuration example, the n-type contact layer is not formed above the n-type low refractive index layer 23, and the n-type low refractive index layer 23 is used as the n-type contact layer. In the above configuration, the occurrence of absorption of the detection target light by the contact layer can be suppressed.

In addition, in the configuration illustrated in FIG. 24 and FIG. 25, in the unit layered structure 31 of the superlattice layer 30, the absorption region 32 may be located on the side opposite to the semiconductor substrate. In this case, it is preferable that each of the semiconductor substrate and the low refractive index layer provided below the superlattice layer 30 is set to the n-type semiconductor layer, and the low refractive index layer provided above the superlattice layer 30 is set to the p-type semiconductor layer.

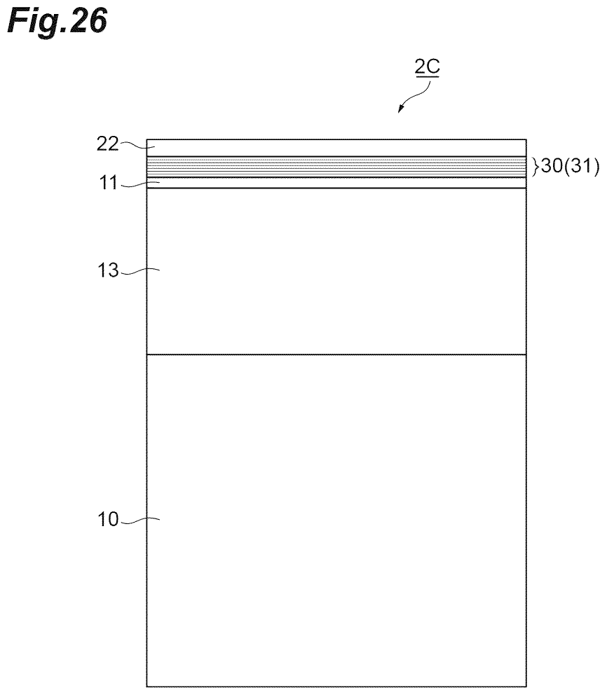

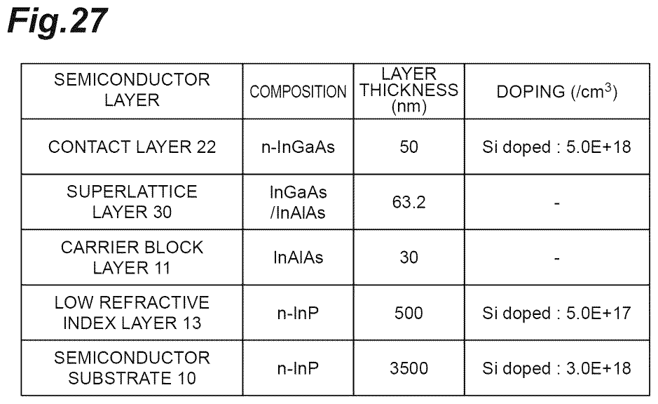

FIG. 26 is a diagram illustrating a basic configuration of a ninth embodiment of the interband photodetector in the form of the semiconductor layered structure. Further, FIG. 27 is a table showing a specific example of the semiconductor layered structure in the interband photodetector illustrated in FIG. 26.

In the interband photodetector 2C according to the present configuration example, in the semiconductor layered structure, an n-type InP substrate 10 with a thickness of 3500 nm is used as the semiconductor substrate. In addition, on the InP substrate 10, in order from the substrate 10 side, an n-type InP low refractive index layer 13 with a thickness of 500 nm, an InAlAs carrier block layer 11 with a thickness of 30 nm, the superlattice layer 30 including the unit layered structure 31, and an n-type InGaAs contact layer 22 with a thickness of 50 nm are stacked.

Further, in the present configuration example, in the unit layered structure 31 of the superlattice layer 30, the absorption region 32 is located on the side of the semiconductor substrate 10. In the above configuration, the carrier block layer 11 has the function of preventing the electrons excited by the interband absorption in the absorption region 32 from moving to the region on the side opposite to the relaxation region 33.

Further, in the present configuration example, the n-type contact layer is not formed between the n-type low refractive index layer 13 and the carrier block layer 11, and the n-type low refractive index layer 13 is used as the n-type contact layer. In the above configuration, the occurrence of absorption of the detection target light by the contact layer can be suppressed.

In addition, in the configuration illustrated in FIG. 26 and FIG. 27, in the unit layered structure 31 of the superlattice layer 30, the absorption region 32 may be located on the side opposite to the semiconductor substrate 10. In this case, it is preferable that the carrier block layer is provided between the superlattice layer 30 and the n-type contact layer 22. Further, it is also possible to use the configuration in which the carrier block layer is not provided. In this case, in the unit layered structure 31 of the superlattice layer 30, the absorption region 32 may be located on the side of the semiconductor substrate 10, or may be located on the side opposite to the semiconductor substrate 10.

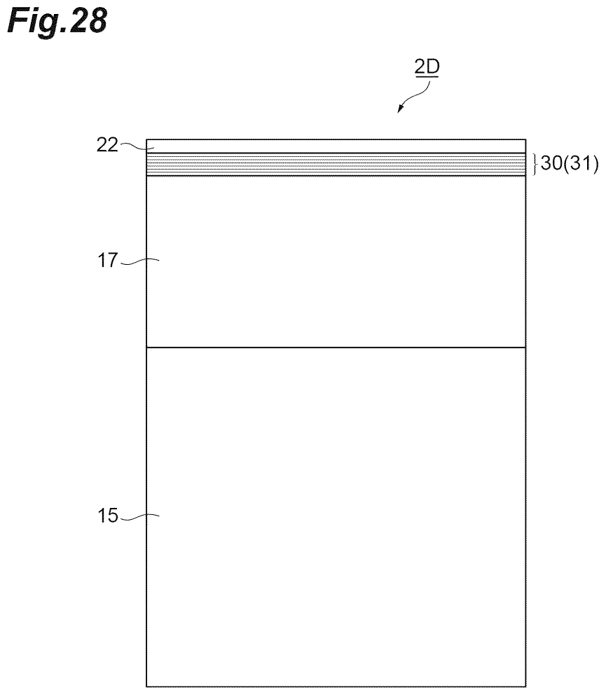

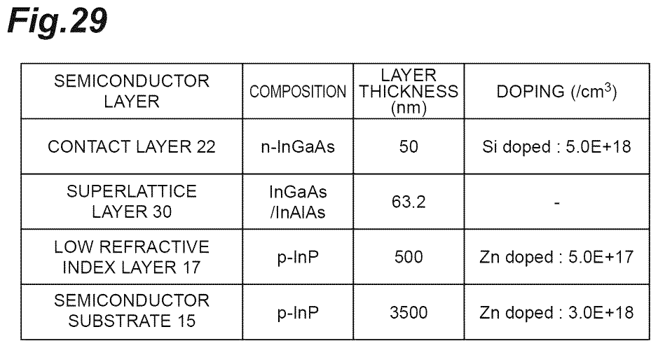

FIG. 28 is a diagram illustrating a basic configuration of a tenth embodiment of the interband photodetector in the form of the semiconductor layered structure. Further, FIG. 29 is a table showing a specific example of the semiconductor layered structure in the interband photodetector illustrated in FIG. 28.

In the interband photodetector 2D according to the present configuration example, in the semiconductor layered structure, a p-type InP substrate 15 with a thickness of 3500 nm is used as the semiconductor substrate. In addition, on the InP substrate 15, in order from the substrate 15 side, a p-type InP low refractive index layer 17 with a thickness of 500 nm, the superlattice layer 30 including the unit layered structure 31, and an n-type InGaAs contact layer 22 with a thickness of 50 nm are stacked.

Further, in the present configuration example, in the unit layered structure 31 of the superlattice layer 30, the absorption region 32 is located on the side of the semiconductor substrate 15. In the above configuration, a depletion layer, which is formed at an interface between the superlattice layer 30 and the p-type low refractive index layer 17 which is the p-type semiconductor layer, has the function of preventing the electrons excited by the interband absorption in the absorption region 32 from moving to the region on the side opposite to the relaxation region 33.

In addition, in the configuration illustrated in FIG. 28 and FIG. 29, in the unit layered structure 31 of the superlattice layer 30, the absorption region 32 may be located on the side opposite to the semiconductor substrate. In this case, it is preferable that each of the semiconductor substrate and the low refractive index layer provided below the superlattice layer 30 is set to the n-type semiconductor layer, and the contact layer provided above the superlattice layer 30 is set to the p-type semiconductor layer.

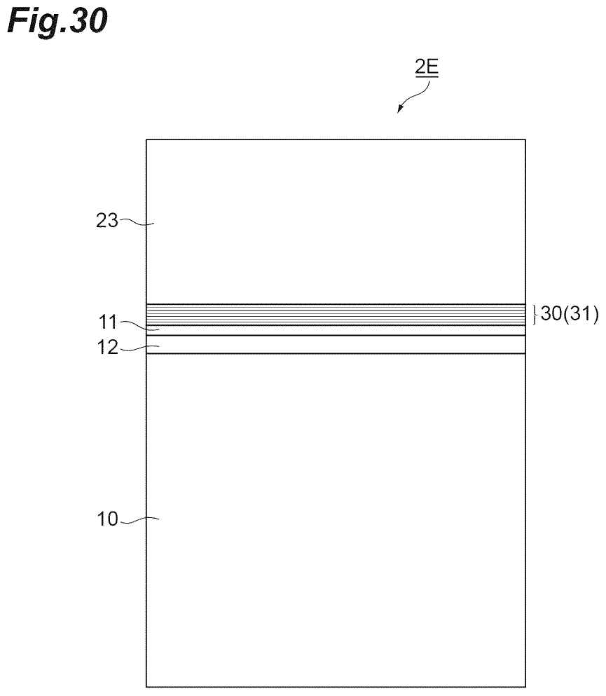

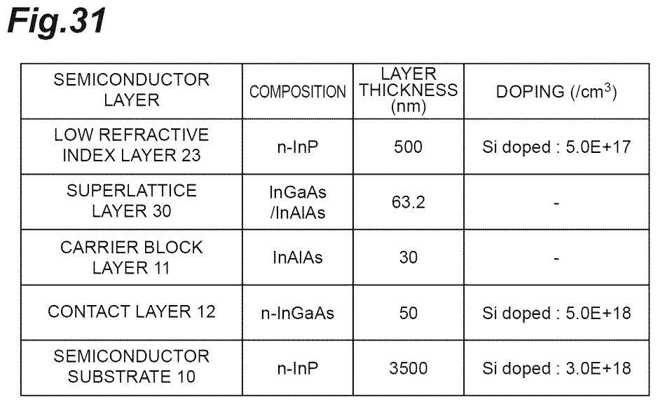

FIG. 30 is a diagram illustrating a basic configuration of an eleventh embodiment of the interband photodetector in the form of the semiconductor layered structure. Further, FIG. 31 is a table showing a specific example of the semiconductor layered structure in the interband photodetector illustrated in FIG. 30.

In the interband photodetector 2E according to the present configuration example, in the semiconductor layered structure, an n-type InP substrate 10 with a thickness of 3500 nm is used as the semiconductor substrate. In addition, on the InP substrate 10, in order from the substrate 10 side, an n-type InGaAs contact layer 12 with a thickness of 50 nm, an InAlAs carrier block layer 11 with a thickness of 30 nm, the superlattice layer 30 including the unit layered structure 31, and an n-type InP low refractive index layer 23 with a thickness of 500 nm are stacked.

Further, in the present configuration example, in the unit layered structure 31 of the superlattice layer 30, the absorption region 32 is located on the side of the semiconductor substrate 10. In the above configuration, the carrier block layer 11 has the function of preventing the electrons excited by the interband absorption in the absorption region 32 from moving to the region on the side opposite to the relaxation region 33.

In addition, in the configuration illustrated in FIG. 30 and FIG. 31, in the unit layered structure 31 of the superlattice layer 30, the absorption region 32 may be located on the side opposite to the semiconductor substrate 10. In this case, it is preferable that the carrier block layer is provided between the superlattice layer 30 and the n-type low refractive index layer 23. Further, it is also possible to use the configuration in which the carrier block layer is not provided. In this case, in the unit layered structure 31 of the superlattice layer 30, the absorption region 32 may be located on the side of the semiconductor substrate 10, or may be located on the side opposite to the semiconductor substrate 10.

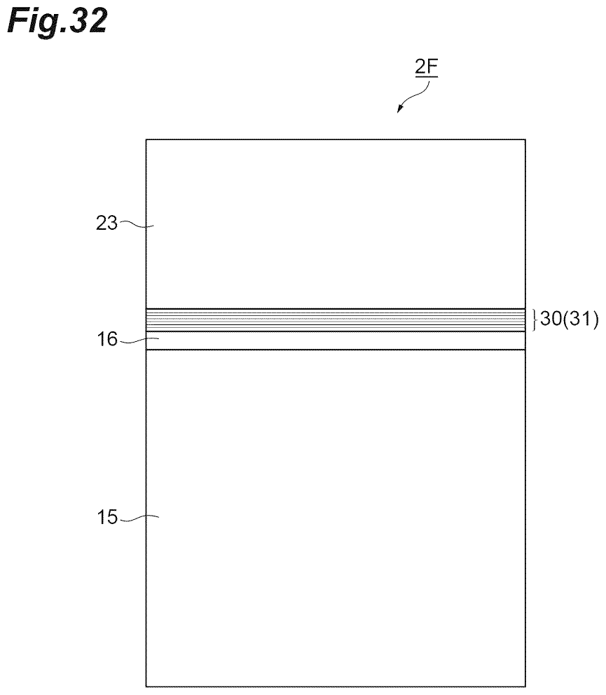

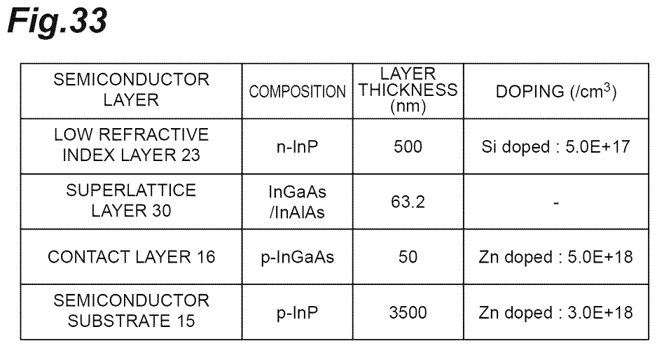

FIG. 32 is a diagram illustrating a basic configuration of a twelfth embodiment of the interband photodetector in the form of the semiconductor layered structure. Further, FIG. 33 is a table showing a specific example of the semiconductor layered structure in the interband photodetector illustrated in FIG. 32.

In the interband photodetector 2F according to the present configuration example, in the semiconductor layered structure, a p-type InP substrate 15 with a thickness of 3500 nm is used as the semiconductor substrate. In addition, on the InP substrate 15, in order from the substrate 15 side, a p-type InGaAs contact layer 16 with a thickness of 50 nm, the superlattice layer 30 including the unit layered structure 31, and an n-type InP low refractive index layer 23 with a thickness of 500 nm are stacked.

Further, in the present configuration example, in the unit layered structure 31 of the superlattice layer 30, the absorption region 32 is located on the side of the semiconductor substrate 15. In the above configuration, a depletion layer, which is formed at an interface between the superlattice layer 30 and the p-type contact layer 16 which is the p-type semiconductor layer, has the function of preventing the electrons excited by the interband absorption in the absorption region 32 from moving to the region on the side opposite to the relaxation region 33.

In addition, in the configuration illustrated in FIG. 32 and FIG. 33, in the unit layered structure 31 of the superlattice layer 30, the absorption region 32 may be located on the side opposite to the semiconductor substrate. In this case, it is preferable that each of the semiconductor substrate and the contact layer provided below the superlattice layer 30 is set to the n-type semiconductor layer, and the low refractive index layer provided above the superlattice layer 30 is set to the p-type semiconductor layer.

The interband photodetector is not limited to the embodiments and configuration examples described above, and various modifications are possible. For example, in the above configuration examples, the InP substrate is used as the semiconductor substrate, and the superlattice layer is formed of InGaAs/InAlAs, and in addition, specifically, various configurations can be used as long as the light absorption and the detection by the interband transition in the quantum well structure are possible, and the above level structure can be realized.

Further, as to the layered structure in the superlattice layer of the interband photodetector and the semiconductor layered structure of the photodetector as the entire element, various structures other than the structures described above can be used. In general, the interband photodetector only needs to be configured to include the semiconductor substrate, and the superlattice layer having the above configuration provided on the semiconductor substrate.

The interband photodetector of a first aspect according to the above embodiment includes (1) a semiconductor substrate; and (2) a superlattice layer provided on the semiconductor substrate, and including a unit layered structure having a type-I quantum well structure including n quantum barrier layers and n quantum well layers, where n is an integer of 3 or more, and (3) the unit layered structure includes an absorption region including at least one quantum well layer, and a relaxation region including m quantum well layers, where m is an integer of 2 or more and n−1 or less, the absorption region has, in its level structure, a detection lower level based on a level in a valence band in the quantum well layer included in the absorption region and functioning as an absorption well layer, and a detection upper level based on a level in a conduction band, the relaxation region has, in its level structure, m relaxation levels each based on a level in the conduction band in each of the m quantum well layers included in the relaxation region, and (4) detection target light is detected by interband absorption from the detection lower level to the detection upper level in the absorption region, and electrons excited by the interband absorption are extracted via a relaxation level structure formed by the m relaxation levels in the relaxation region.

In the interband photodetector of a second aspect, in the above configuration of the first aspect, a band gap energy in each of the m quantum well layers included in the relaxation region may be set to be larger than a band gap energy in the quantum well layer included in the absorption region.

In the interband photodetector of a third aspect, in the above configuration of the first or second aspect, an energy difference between a level in the valence band and the relaxation level in each of the m quantum well layers included in the relaxation region may be set to be larger than an energy difference between the detection lower level and the detection upper level in the quantum well layer included in the absorption region.

In the interband photodetector of a fourth aspect, in the above configuration of the third aspect, the energy difference between the level in the valence band and the relaxation level in each of the m quantum well layers included in the relaxation region may be set to be larger than a detection energy of the detection target light.

By using each of the above configurations, occurrence of the light absorption in the relaxation region including the m relaxation levels can be suppressed by the setting of the energy difference and the like. As a result of the above, the detection operation of the light by the interband light absorption in the absorption region and the electron relaxation in the relaxation region can be suitably realized, thereby making it possible to improve the detection efficiency of the light by the photodetector.

In the interband photodetector of a fifth aspect, in the above configuration of any one of the first to fourth aspects, in the quantum well layer included in the absorption region, the detection upper level may be a level arising from a ground level in a subband level structure of the conduction band.

In the interband photodetector of a sixth aspect, in the above configuration of any one of the first to fifth aspects, in each of the m quantum well layers included in the relaxation region, the relaxation level may be a level arising from a ground level in a subband level structure of the conduction band.

By using each of the above configurations, by appropriately setting the level structure formed by the detection upper level and the m relaxation levels in the subband level structure of the conduction band, the detection operation of the light by the interband light absorption in the absorption region and the electron relaxation in the relaxation region can be suitably realized.

In the interband photodetector of a seventh aspect, in the above configuration of any one of the first to sixth aspects, in the unit layered structure, each of the n quantum barrier layers and the n quantum well layers may be formed of an i-type semiconductor layer.

As described above, by setting each of the quantum barrier layers and the quantum well layers included in the unit layered structure of the superlattice layer to the undoped i-type semiconductor layer, the detection of the detection target light using the interband absorption can be suitably realized.

In the interband photodetector of an eighth aspect, in the above configuration of any one of the first to seventh aspects, the superlattice layer may include a plurality of unit layered structures, each including the absorption region and the relaxation region, as the unit layered structure.

As described above, in the case in which the superlattice layer has the cascade structure in which the plurality of unit layered structures are stacked in multiple stages, the interband photodetector described above functions as the interband cascade detector. In addition, as to the superlattice layer, the superlattice layer may also have the configuration including the single unit layered structure.

In the interband photodetector of a ninth aspect, in the above configuration of any one of the first to eighth aspects, in the unit layered structure, the absorption region may include a single quantum well layer.

In the interband photodetector of a tenth aspect, in the above configuration of any one of the first to eighth aspects, in the unit layered structure, the absorption region may include a plurality of quantum well layers.

As in each of the above configurations, the quantum well layer included in the absorption region and functioning as the absorption well layer may be configured by the single quantum well layer or the plurality of quantum well layers. In the case in which the absorption region includes the single quantum well layer, the configuration of the absorption region can be simplified. Further, in the case in which the absorption region includes the plurality of quantum well layers, the detection efficiency of the light by the interband absorption can be improved.

In the interband photodetector of an eleventh aspect, in the above configuration of any one of the first to tenth aspects, a carrier block layer may be provided in a region adjacent to the absorption region, wherein the adjacent region is selected from one of a region on a side of the semiconductor substrate with respect to the superlattice layer and a region on a side opposite to the semiconductor substrate with respect to the superlattice layer.

In the interband photodetector of a twelfth aspect, in the above configuration of any one of the first to eleventh aspects, a p-type semiconductor layer may be provided in a region adjacent to the absorption region, wherein the adjacent region is selected from one of a region on a side of the semiconductor substrate with respect to the superlattice layer and a region on a side opposite to the semiconductor substrate with respect to the superlattice layer.

By using each of the above configurations, by the carrier block layer or the p-type semiconductor layer provided on the absorption region side with respect to the superlattice layer, the electrons excited by the interband absorption in the absorption region are prevented from moving to the region on the side opposite to the relaxation region, thereby making it possible to improve the extraction efficiency of the electrons by using the m relaxation levels in the relaxation region.

In the interband photodetector of a thirteenth aspect, in the above configuration of any one of the first to twelfth aspects, a low refractive index layer may be provided in a region on a side of the semiconductor substrate with respect to the superlattice layer.

In the interband photodetector of a fourteenth aspect, in the above configuration of any one of the first to thirteenth aspects, a low refractive index layer may be provided in a region on a side opposite to the semiconductor substrate with respect to the superlattice layer.

As in each of the above configurations, by providing the low refractive index layer functioning as the cladding layer for the superlattice layer in at least one of the region on the side of the semiconductor substrate with respect to the superlattice layer and the region on the side opposite to the semiconductor substrate with respect to the superlattice layer, the detection target light can be confined in the superlattice layer, thereby making it possible to improve the detection efficiency of the light by the photodetector.

In the interband photodetector of a fifteenth aspect, in the above configuration of any one of the first to fourteenth aspects, in the absorption region, an energy difference between the detection lower level and the detection upper level may be set to be larger than an energy of a longitudinal optical phonon.

In the interband photodetector of a sixteenth aspect, in the above configuration of any one of the first to fifteenth aspects, in the relaxation region, an energy difference between adjacent relaxation levels out of the m relaxation levels may be set to be larger than an energy of a longitudinal optical phonon.

By using each of the above configurations, in the relaxation level structure of the electrons formed by the m relaxation levels in the relaxation region, the high-speed relaxation of the electrons by the longitudinal optical phonon scattering can be used. In this case, the electrons excited to the detection upper level by the light absorption move to the relaxation level in the relaxation region by the resonant tunneling effect, and further, in the relaxation level structure formed by the m relaxation levels, the electrons are rapidly extracted by the relaxation process including the high-speed relaxation due to the longitudinal optical phonon scattering.

In the interband photodetector of a seventeenth aspect, in the above configuration of any one of the first to sixteenth aspects, in the unit layered structure, the type-I quantum well structure may be set to a structure in which a valence band upper edge in the quantum well layer is higher than a valence band upper edge in the adjacent quantum barrier layer.

As to the type-I quantum well structure constituting the unit layered structure in the superlattice layer, specifically, for example, the structure described above can be used.

The present invention can be used as an interband photodetector which is capable of being suitably applied to detection of light at a desired detection wavelength over a wide wavelength range.

From the invention thus described, it will be obvious that the invention may be varied in many ways. Such variations are not to be regarded as a departure from the spirit and scope of the invention, and all such modifications as would be obvious to one skilled in the art are intended for inclusion within the scope of the following claims.

What is claimed is:

1. An interband photodetector comprising:
a semiconductor substrate; and
a superlattice layer provided on the semiconductor substrate, and including a unit layered structure having a type-I quantum well structure including n quantum barrier layers and n quantum well layers, where n is an integer of 3 or more, wherein
the unit layered structure includes an absorption region including at least one quantum well layer, and a relaxation region including m quantum well layers, where m is an integer from 2 to n−1,
the absorption region has, in its level structure, a detection lower level arising from a level in a valence band in the quantum well layer included in the absorption region and functioning as an absorption well layer, and a detection upper level arising from a level in a conduction band,
the relaxation region has, in its level structure, m relaxation levels each arising from a level in the conduction band in each of the m quantum well layers included in the relaxation region, and
detection target light is detected by interband absorption from the detection lower level to the detection upper level in the absorption region, and electrons excited by the interband absorption are extracted via a relaxation level structure formed by the m relaxation levels in the relaxation region.

2. The interband photodetector according to claim 1, wherein a band gap energy in each of the m quantum well layers included in the relaxation region is set to be larger than a band gap energy in the quantum well layer included in the absorption region.

3. The interband photodetector according to claim 1, wherein an energy difference between a level in the valence band and the relaxation level in each of the m quantum well layers included in the relaxation region is set to be larger than an energy difference between the detection lower level and the detection upper level in the quantum well layer included in the absorption region.

4. The interband photodetector according to claim 3, wherein the energy difference between the level in the valence band and the relaxation level in each of the m quantum well layers included in the relaxation region is set to be larger than a detection energy of the detection target light.

5. The interband photodetector according to claim 1, wherein, in the quantum well layer included in the absorption region, the detection upper level is a level arising from a ground level in a subband level structure of the conduction band.

6. The interband photodetector according to claim 1, wherein, in each of the m quantum well layers included in the relaxation region, the relaxation level is a level arising from a ground level in a subband level structure of the conduction band.

7. The interband photodetector according to claim 1, wherein, in the unit layered structure, each of the n quantum barrier layers and the n quantum well layers is formed of an i-type semiconductor layer.

8. The interband photodetector according to claim 1, wherein the superlattice layer includes a plurality of unit layered structures, each including the absorption region and the relaxation region, as the unit layered structure.

9. The interband photodetector according to claim 1, wherein, in the unit layered structure, the absorption region includes a single quantum well layer.

10. The interband photodetector according to claim 1, wherein, in the unit layered structure, the absorption region includes a plurality of quantum well layers.

11. The interband photodetector according to claim 1, wherein a carrier block layer is provided in a region adjacent to the absorption region, selected from a region on a side of the semiconductor substrate with respect to the superlattice layer and a region on a side opposite to the semiconductor substrate with respect to the superlattice layer.

12. The interband photodetector according to claim 1, wherein a p-type semiconductor layer is provided in a region adjacent to the absorption region, selected from a region on a side of the semiconductor substrate with respect to the superlattice layer and a region on a side opposite to the semiconductor substrate with respect to the superlattice layer.

13. The interband photodetector according to claim 1, wherein a low refractive index layer is provided in a region on a side of the semiconductor substrate with respect to the superlattice layer.

14. The interband photodetector according to claim 1, wherein a low refractive index layer is provided in a region on a side opposite to the semiconductor substrate with respect to the superlattice layer.

15. The interband photodetector according to claim 1, wherein, in the absorption region, an energy difference between the detection lower level and the detection upper level is set to be larger than an energy of a longitudinal optical phonon.

16. The interband photodetector according to claim 1, wherein, in the relaxation region, an energy difference between adjacent relaxation levels out of the m relaxation levels is set to be larger than an energy of a longitudinal optical phonon.

17. The interband photodetector according to claim 1, wherein, in the unit layered structure, the type-I quantum well structure is a structure in which a valence band upper edge in the quantum well layer is higher than a valence band upper edge in the adjacent quantum barrier layer.
